(19) United States
(12) Patent Application Publication
(10) Pub. No.: US 2026/0269567 A1
(43) Pub. Date: Sep. 10, 2026

(54) SURFACE-EMITTING LASER

(71) Applicant: SONY GROUP CORPORATION, TOKYO (JP)

(72) Inventors: YASUTAKA HIGA, KANAGAWA (JP); HIROYUKI TAHARA, TOKYO (JP); RINTARO KODA, KANAGAWA (JP); HIDEKI WATANABE, TOKYO (JP); GYONGSOK SONG, KANAGAWA (JP); TATSUYA MATOU, KANAGAWA (JP); SHUHEI YAMAGUCHI, KANAGAWA (JP); KOSHIRO WADA, KANAGAWA (JP)

(21) Appl. No.: 19/164,416

(22) PCT Filed: Feb. 19, 2024
(86) PCT No.: PCT/JP2024/005640

§ 371 Date: Sep. 11, 2025

(30) Foreign Application Priority Data
Mar. 29, 2023 (JP) 2023-053526

(51) Int. Cl. H01S 5/183

(52) U.S. Cl. CPC H01S 5/18308; H01S 5/18361

(57) ABSTRACT

To provide a surface-emitting laser with a high degree of freedom in setting an effective refractive index distribution in an in-plane direction of a light-trapping structure. A surface-emitting laser according to the present technique includes a resonator including: first and second reflecting structures; and an active layer arranged between the first and second reflecting structures, wherein the resonator includes, between a surface of the first reflecting structure on an opposite side to a side of the active layer and the active layer and/or between a surface of the second reflecting structure on an opposite side to a side of the active layer and the active layer, a metasurface for generating in an in-plane direction an effective refractive index distribution that traps light. With the surface-emitting laser according to the present technique, a surface-emitting laser with a high degree of freedom in setting an effective refractive index distribution in an in-plane direction of a light-trapping structure can be provided.

### TECHNICAL FIELD

The technique pertaining to the present disclosure (hereinafter, also referred to as a “present technique”) relates to a surface-emitting laser.

### BACKGROUND ART

Conventionally, surface-emitting lasers (VCSELs) that emit light in a direction perpendicular to a substrate and that have a light-trapping structure are known.

For example, NPL 1 discloses a surface-emitting laser having an oxide-confined structure as a light-trapping structure.

For example, NPL 2 discloses a surface-emitting laser having a loss distribution formation (surface relief) by a surface structure as a light-trapping structure.

### CITATION LIST

### Patent Literature

[NPL 1] B. Weigl; M. Grabherr; C. Jung; R. Jager; G. Reiner; R. Michalzik; D. Sowada; K. J. Ebeling, “High-performance oxide-confined GaAs VCSELs”, IEEE Journal of Selected Topics in Quantum Electronics (Volume: 3, Issue: 2, April 1997) DOI: 10.1109/2944.605686
[NPL 2] H. J. Unold: S. W. Z. Mahmoud; R. Jager: M. Grabherr; R. Michalzik; K. J. Ebeling, “Large-area single-mode VCSELs and the self-aligned surface relief”, IEEE Journal of Selected Topics in Quantum Electronics (Volume: 7, Issue: 2, March-April 2001) DOI: 10.1109/2944.954155

### SUMMARY

### Technical Problem

However, with a conventional surface-emitting laser, a refractive index distribution and a loss distribution in an in-plane direction of a light-trapping structure can be set only discretely.

In consideration thereof, a primary object of the present technique is to provide a surface-emitting laser with a high degree of freedom in setting an effective refractive index distribution in an in-plane direction of a light-trapping structure.

### Solution to Problem

The present technique is a surface-emitting laser, including a resonator that includes:
first and second reflecting structures; and
an active layer arranged between the first and second reflecting structures, wherein the resonator includes, between a surface of the first reflecting structure on an opposite side to a side of the active layer and the active layer and/or between a surface of the second reflecting structure on an opposite side to a side of the active layer and the active layer, a metasurface for generating in an in-plane direction an effective refractive index distribution that traps light.

A direction of resonance of the resonator may be perpendicular to the in-plane direction.

The metasurface may be set not to form a stopband at an oscillation wavelength of the surface-emitting laser with respect to light propagating in the in-plane direction.

The metasurface may be arranged between the first reflecting structure and the active layer and/or between the second reflecting structure and the active layer.

The metasurface may be arranged inside at least one of the first and second reflecting structures.

The metasurface may have an area in which an effective refractive index gradually decreases from a reference point to an outer edge side in the in-plane direction.

The metasurface may have an area in which an effective refractive index decreases in a plurality of stages from a reference point to an outer edge side in the in-plane direction.

The metasurface may have a first area including a plurality of unit structures aligned in the in-plane direction and a second area surrounding each of the plurality of unit structures and having a material refractive index different from that of the first area.

The plurality of unit structures may be arranged at a predetermined pitch in the in-plane direction, and a duty ratio, which is a ratio of the unit structures to the pitch, may vary in the in-plane direction.

The first area may have a higher material refractive index than the second area, and the duty ratio may gradually decrease from a reference point to an outer edge side in the in-plane direction.

The first area may have a lower material refractive index than the second area, and the duty ratio may gradually increase from a reference point to an outer edge side in the in-plane direction.

The first area may have a higher material refractive index than the second area, and the duty ratio may decrease in a plurality of stages from a reference point to an outer edge side in the in-plane direction.

The first area may have a lower material refractive index than the second area, and the duty ratio may increase in a plurality of stages from a reference point to an outer edge side in the in-plane direction.

Each of the plurality of unit structures may be smaller than an oscillation wavelength of the surface-emitting laser. The plurality of unit structures may be arranged at a predetermined pitch in the in-plane direction, and the pitch may be shorter than an emission wavelength of the active layer.

Each of the plurality of unit structures may have shape anisotropy in the in-plane direction.

Each of the plurality of unit structures may have the same shape anisotropy.

A transverse cross-sectional shape of each of the plurality of unit structures may be any of a polygonal shape, a circular shape, and an elliptical shape.

A transverse cross-sectional shape of each of the plurality of unit structures may be a shape with two-fold symmetry.

A transverse cross-sectional shape of each of the plurality of unit structures may be a shape with N-fold symmetry (N≥3).

The plurality of unit structures may be periodically arranged.

The plurality of unit structures may be arranged in any of a square lattice pattern, a rectangular lattice pattern, a six law lattice pattern, and a rhombic lattice pattern.

A longitudinal cross-sectional shape of each of the plurality of unit structures may be any of a rectangular shape, at least a part of a circular shape, at least a part of an elliptical shape, and a trapezoidal shape.

The plurality of unit structures may be arranged at a position deviated from a current pathway during driving in the resonator.

Both the first and second reflecting structures may have a reflectance of 90% or higher with respect to an oscillation wavelength of the surface-emitting laser.

One of the first and second areas may be a gas or a vacuum and the other may be a dielectric body or a semiconductor.

One of the first and second areas may be a dielectric body and the other may be a semiconductor.

The first and second areas may be dielectric bodies.

An upper end and a lower end of a longitudinal cross-section of each of the plurality of unit structures may exist on a same plane.

An outer edge of a longitudinal cross-section of each of the plurality of unit structures may include a curved line.

The first reflecting structure and/or the second reflecting structure may include at least one of a semiconductor multilayer reflector, a dielectric multilayer reflector, a metal reflector, and high-contrast gratings. The resonator may further include a current constriction area arranged between a surface of the first reflecting structure on an opposite side to a side of the active layer and a surface of the second reflecting structure on an opposite side to a side of the active layer.

### BRIEF DESCRIPTION OF DRAWINGS

FIG. 1 is a sectional view of a surface-emitting laser according to a first embodiment of the present technique.

FIG. 2 is a plan view of the surface-emitting laser according to the first embodiment of the present technique.

FIG. 3 is a diagram schematically showing an example of an effective refractive index distribution of a metasurface of the surface-emitting laser according to the first embodiment of the present technique.

FIG. 4 is a diagram showing arrangement example 1 of a plurality of unit structures of the metasurface of the surface-emitting laser according to the first embodiment of the present technique.

FIGS. 5A and 5B are each a diagram for describing arrangement example 1 of the plurality of unit structures of the metasurface of the surface-emitting laser according to the first embodiment of the present technique.

FIGS. 6A and 6B are each a diagram for describing arrangement example 2 of the plurality of unit structures of the metasurface of the surface-emitting laser according to the first embodiment of the present technique.

FIG. 7 is a diagram schematically showing another example of the effective refractive index distribution of the metasurface of the surface-emitting laser according to the first embodiment of the present technique.

FIG. 8 is a diagram showing arrangement example 3 of the plurality of unit structures of the metasurface of the surface-emitting laser according to the first embodiment of the present technique.

FIG. 9 is a diagram for describing arrangement example 3 of the plurality of unit structures of the metasurface of the surface-emitting laser according to the first embodiment of the present technique.

FIG. 10 is a diagram for describing arrangement example 4 of the plurality of unit structures of the metasurface of the surface-emitting laser according to the first embodiment of the present technique.

FIGS. 11A to 11D are each a plan view of each of configuration examples 1 to 4 of the unit structure of the metasurface of the surface-emitting laser according to the first embodiment of the present technique.

FIGS. 12A to 12D are each a plan view of each of configuration examples 5 to 8 of the unit structure of the metasurface of the surface-emitting laser according to the first embodiment of the present technique.

FIGS. 13A and 13B are each a plan view of each of configuration examples 9 and 10 of the unit structure of the metasurface of the surface-emitting laser according to the first embodiment of the present technique.

FIGS. 14A and 14B are each a plan view of each of configuration examples 11 and 12 of the unit structure of the metasurface of the surface-emitting laser according to the first embodiment of the present technique.

FIGS. 15A and 15B are each a plan view of each of configuration examples 13 and 14 of the unit structure of the metasurface of the surface-emitting laser according to the first embodiment of the present technique.

FIGS. 16A and 16B are each a plan view of each of configuration examples 15 and 16 of the unit structure of the metasurface of the surface-emitting laser according to the first embodiment of the present technique.

FIGS. 17A and 17B are each a plan view of each of arrangement patterns 1 and 2 of the unit structure of the metasurface of the surface-emitting laser according to the first embodiment of the present technique.

FIGS. 18A and 18B are each a plan view of each of arrangement patterns 3 and 4 of the unit structure of the metasurface of the surface-emitting laser according to the first embodiment of the present technique.

FIG. 19 is a flow chart for describing an example of a manufacturing method of the surface-emitting laser shown in FIG. 1.

FIGS. 20A and 20B are sectional views of each step of the example of the manufacturing method of the surface-emitting laser shown in FIG. 1.

FIGS. 21A and 21B are sectional views of each step of the example of the manufacturing method of the surface-emitting laser shown in FIG. 1.

FIG. 22 is a sectional view of each step of the example of the manufacturing method of the surface-emitting laser shown in FIG. 1.

FIG. 23 is a sectional view of each step of the example of the manufacturing method of the surface-emitting laser shown in FIG. 1.

FIG. 24 is a sectional view of each step of the example of the manufacturing method of the surface-emitting laser shown in FIG. 1.

FIG. 25 is a sectional view of each step of the example of the manufacturing method of the surface-emitting laser shown in FIG. 1.

FIG. 26 is a sectional view of each step of the example of the manufacturing method of the surface-emitting laser shown in FIG. 1.

FIG. 27 is a sectional view of each step of the example of the manufacturing method of the surface-emitting laser shown in FIG. 1.

FIG. 28 is a sectional view of each step of the example of the manufacturing method of the surface-emitting laser shown in FIG. 1.

FIG. 29 is a sectional view of each step of the example of the manufacturing method of the surface-emitting laser shown in FIG. 1.

FIG. 30 is a sectional view of a surface-emitting laser according to a second embodiment of the present technique.

FIG. 31 is a plan view of the surface-emitting laser according to the second embodiment of the present technique.

FIG. 32 is a flow chart for describing an example of a manufacturing method of the surface-emitting laser shown in FIG. 30.

FIGS. 33A to 33C are sectional views of each step of the example of the manufacturing method of the surface-emitting laser shown in FIG. 30.

FIGS. 34A and 34B are sectional views of each step of the example of the manufacturing method of the surface-emitting laser shown in FIG. 30.

FIGS. 35A and 35B are sectional views of each step of the example of the manufacturing method of the surface-emitting laser shown in FIG. 30.

FIGS. 36A and 36B are sectional views of each step of the example of the manufacturing method of the surface-emitting laser shown in FIG. 30.

FIGS. 37A and 37B are sectional views of each step of the example of the manufacturing method of the surface-emitting laser shown in FIG. 30.

FIGS. 38A and 38B are sectional views of each step of the example of the manufacturing method of the surface-emitting laser shown in FIG. 30.

FIG. 39 is a sectional view of each step of the example of the manufacturing method of the surface-emitting laser shown in FIG. 30.

FIG. 40 is a sectional view of a surface-emitting laser according to a third embodiment of the present technique.

FIG. 41 is a plan view of the surface-emitting laser according to the third embodiment of the present technique.

FIG. 42 is a flow chart for describing an example of a manufacturing method of the surface-emitting laser shown in FIG. 40.

FIGS. 43A and 43B are sectional views of each step of the example of the manufacturing method of the surface-emitting laser shown in FIG. 40.

FIGS. 44A to 44C are sectional views of each step of the example of the manufacturing method of the surface-emitting laser shown in FIG. 40.

FIGS. 45A and 45B are sectional views of each step of the example of the manufacturing method of the surface-emitting laser shown in FIG. 40.

FIGS. 46A and 46B are sectional views of each step of the example of the manufacturing method of the surface-emitting laser shown in FIG. 40.

FIGS. 47A and 47B are sectional views of each step of the example of the manufacturing method of the surface-emitting laser shown in FIG. 40.

FIGS. 48A and 48B are sectional views of each step of the example of the manufacturing method of the surface-emitting laser shown in FIG. 40.

FIGS. 49A and 49B are sectional views of each step of the example of the manufacturing method of the surface-emitting laser shown in FIG. 40.

FIG. 50 is a sectional view of a surface-emitting laser according to a fourth embodiment of the present technique.

FIG. 51 is a flow chart for describing an example of a manufacturing method of the surface-emitting laser shown in FIG. 50.

FIGS. 52A and 52B are sectional views of each step of the example of the manufacturing method of the surface-emitting laser shown in FIG. 50.

FIGS. 53A and 53B are sectional views of each step of the example of the manufacturing method of the surface-emitting laser shown in FIG. 50.

FIG. 54 is a sectional view of each step of the example of the manufacturing method of the surface-emitting laser shown in FIG. 50.

FIGS. 55A and 55B are sectional views of each step of the example of the manufacturing method of the surface-emitting laser shown in FIG. 50.

FIGS. 56A and 56B are sectional views of each step of the example of the manufacturing method of the surface-emitting laser shown in FIG. 50.

FIGS. 57A and 57B are sectional views of each step of the example of the manufacturing method of the surface-emitting laser shown in FIG. 50.

FIG. 58 is a sectional view of a surface-emitting laser according to modification 1 of the first embodiment of the present technique.

FIG. 59 is a sectional view of a surface-emitting laser according to modification 1 of the second embodiment of the present technique.

FIG. 60 is a sectional view of a surface-emitting laser according to modification 2 of the second embodiment of the present technique.

FIG. 61 is a sectional view of a surface-emitting laser according to modification 3 of the second embodiment of the present technique.

FIG. 62 is a sectional view of a surface-emitting laser according to modification 4 of the second embodiment of the present technique.

FIG. 63 is a sectional view of a surface-emitting laser according to modification 5 of the second embodiment of the present technique.

FIG. 64 is a sectional view of a surface-emitting laser according to modification 2 of the first embodiment of the present technique.

FIG. 65 is a sectional view of a surface-emitting laser according to modification 6 of the second embodiment of the present technique.

FIG. 66 is a sectional view of a surface-emitting laser according to modification 3 of the first embodiment of the present technique.

FIG. 67 is a sectional view of a surface-emitting laser according to modification 4 of the first embodiment of the present technique.

FIGS. 68A and 68B are sectional views of each step of an example of a manufacturing method of the surface-emitting laser shown in FIG. 67.

FIGS. 69A and 69B are sectional views of each step of the example of the manufacturing method of the surface-emitting laser shown in FIG. 67.

FIG. 70 is a sectional view of each step of the example of the manufacturing method of the surface-emitting laser shown in FIG. 67.

FIG. 71 is a sectional view of a surface-emitting laser according to modification 1 of the fourth embodiment of the present technique.

FIG. 72 is a sectional view of a surface-emitting laser according to modification 5 of the first embodiment of the present technique.

FIG. 73 is a sectional view of a surface-emitting laser according to modification 6 of the first embodiment of the present technique.

FIGS. 74A and 74B are each a diagram showing each of longitudinal cross-section configuration examples 1 and 2 of a metasurface of a surface-emitting laser according to the present technique.

FIGS. 75A and 75B are each a diagram showing each of longitudinal cross-section configuration examples 3 and 4 of a metasurface of a surface-emitting laser according to the present technique.

FIGS. 76A and 76B are each a diagram showing each of longitudinal cross-section configuration examples 5 and 6 of a metasurface of a surface-emitting laser according to the present technique.

FIG. 77 is a diagram showing longitudinal cross-section configuration example 7 of a metasurface of a surface-emitting laser according to the present technique.

FIGS. 78A and 78B are each a diagram showing each of longitudinal cross-section configuration examples 8 and 9 of a metasurface of a surface-emitting laser according to the present technique.

FIG. 79 is a diagram showing an application example of the surface-emitting laser according to the first embodiment of the present technique to a distance measurement apparatus.

FIG. 80 is a block diagram showing an example of a schematic configuration of a vehicle control system.

FIG. 81 is an explanatory diagram showing an example of an installation position of a distance measurement apparatus.

### DESCRIPTION OF EMBODIMENTS

Hereinafter, preferred embodiments of the present technique will be described in detail with reference to the accompanying drawings. In the present specification and the drawings, components having substantially a same functional configuration will be denoted by same reference signs and overlapping descriptions thereof will not be repeated. The embodiments described below are representative embodiments of the present technique and are not to be construed as narrowing the scope of the present technique. Even if a surface-emitting laser according to the present technique is described in the present specification as producing a plurality of advantageous effects, the surface-emitting laser according to the present technique need only produce at least one advantageous effect. The advantageous effects described in the present specification are merely exemplary and are not restrictive, and other advantageous effects may be produced.

In addition, descriptions will be given in an order described below.
0. Introduction
1. Surface-emitting laser according to first embodiment of present technique
2. Surface-emitting laser according to second embodiment of present technique
3. Surface-emitting laser according to third embodiment of present technique
4. Surface-emitting laser according to fourth embodiment of present technique
5. Modifications of present technique
6. Example of application to electronic device
7. Example of application of surface-emitting laser to distance measurement apparatus
8. Example of distance measurement apparatus mounted to mobile body

### 0. INTRODUCTION

In vertical cavity surface-emitting lasers (VCSELs), it is common to trap light in a direction (transverse direction) perpendicular to an emission direction to form a transverse mode and enable efficient laser oscillation.

For example, an oxide-confined structure (for example, NPL 1) as a light-trapping structure enables light trapping and current constriction to be performed at the same time and is a technique used in a very large number of VCSELs. While this technique is mature today, on the other hand, in principle, side surfaces of a resonator need to be exposed by etching because AlGaAs of high Al composition must be exposed to high-temperature water vapor to form an AlₓO_{y} layer. When taking structures realized by conventional VCSEL techniques one step further to fabricate a 2D array structure with an extremely high fill factor, an ultra-small area VCSEL, a narrow pitch array, and the like, drawbacks such as portions required for etching becoming non-light-emitting areas and the fabricated structure having a high aspect ratio become apparent.

Light-trapping methods other than oxide confinement include loss distribution formation (surface relief) by a surface structure (NPL 2), formation of transverse effective refractive index distribution using regrowth, transverse light trapping using photonic crystal structures, and formation of transverse effective refractive index distribution by wafer bonding. While each method has its own advantages and disadvantages, they all have one thing in common: values of the refractive index and loss can only be set discretely. In other words, conventional light-trapping structures are limited to designs such as a step-index in an analogy of an optical fiber and it is difficult to achieve designs such as a graded-index which allows more flexible and continuous control of light distributions and emission angles.

After careful consideration, the present inventors developed the surface-emitting laser according to the present technique as a surface-emitting laser with a high degree of freedom in setting an effective refractive index distribution in an in-plane direction of a light-trapping structure.

Specifically, the present inventors focused on the fact that metasurfaces enable an effective refractive index distribution in the in-plane direction to be flexibly designed, and succeeded in applying the technique of trapping light by utilizing a difference in effective refractive indices of metasurfaces in the in-plane direction to a light-trapping structure of a surface-emitting laser.

Hereinafter, the surface-emitting laser according to the present technique will be described in detail using several embodiments. Hereinafter, for the sake of convenience, upward in sectional views will be described as up and downward will be described as down.

### 1. SURFACE-EMITTING LASER ACCORDING TO FIRST EMBODIMENT OF PRESENT TECHNIQUE

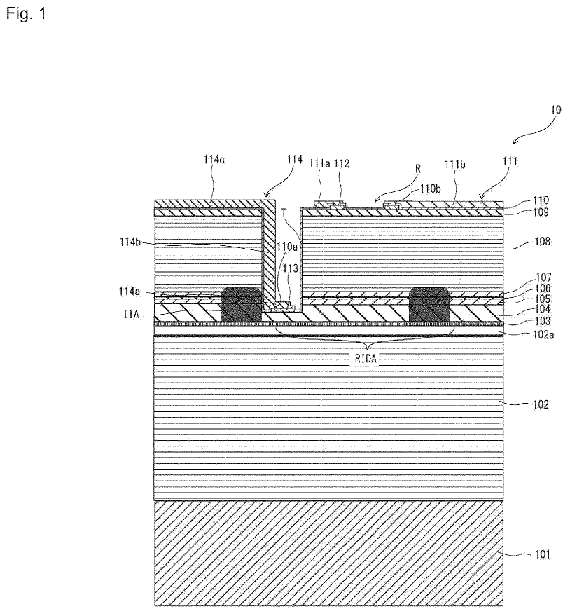

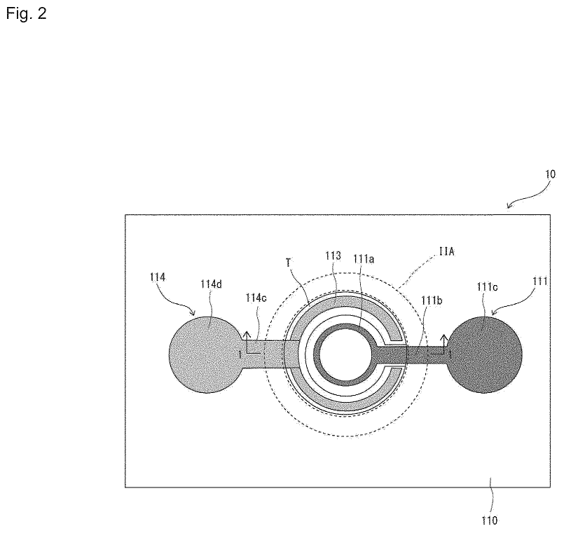

FIG. 1 is a sectional view of a surface-emitting laser 10 according to a first embodiment of the present technique. FIG. 2 is a plan view of the surface-emitting laser 10. FIG. 1 is a sectional view taken along line 1-1 in FIG. 2.

### <<Configuration of Surface-Emitting Laser>>

### [Overall Configuration]

The surface-emitting laser 10 according to Example 1 is a vertical-cavity surface-emitting laser (VCSEL). For example, as shown in FIGS. 1 and 2, the surface-emitting laser 10 includes a resonator R including: first and second reflecting structures 102 and 108; and an active layer 106 arranged between the first and second reflecting structures 102 and 108. The surface-emitting laser 10 is a top-emitting VCSEL. The surface-emitting laser 10 is driven, for example, by a laser driver. The surface-emitting laser 10 is mounted, for example, to the laser driver by junction-up.

The resonator R includes a metasurface 103 arranged between a surface of the first reflecting structure 102 on an opposite side to a side of the active layer 106 and the active layer 106. As an example, the metasurface 103 is arranged between the first reflecting structure 102 and the active layer 106. A direction of resonance of the resonator R is perpendicular to an in-plane direction of the metasurface 103.

As an example, the surface-emitting laser 10 further includes a substrate 101 arranged on an opposite side (lower side) of the first reflecting structure 102 to the side of the active layer 106. As an example, the resonator R further includes a first contact layer 104 arranged between the metasurface 103 and the active layer 106, a first cladding layer 105 arranged between the first contact layer 104 and the active layer 106, a second cladding layer 107 arranged between the active layer 106 and the second reflecting structure 108, and a second contact layer 109 arranged on an opposite side (upper side) of the second reflecting structure 108 to the side of the active layer 106.

In other words, as an example, in the surface-emitting laser 10, the first reflecting structure 102, the metasurface 103, the first contact layer 104, the first cladding layer 105, the active layer 106, the second cladding layer 107, the second reflecting structure 108, and the second contact layer 109 are stacked in this order on the substrate 101.

A trench T (groove) with, for example, a C-shape in a plan view is formed on a surface (upper surface) of the resonator R on a side of the second contact layer 109. As an example, a bottom surface of the trench T is positioned in the first contact layer 104. A first contact metal 113 with, for example, a C-shape in a plan view is provided along the trench T on the bottom surface of the trench T.

A second contact metal 112 with, for example, a ring shape is provided inside the trench T in a plan view on an upper surface of the second contact layer 109. Conversely, the trench T is formed in, for example, a C-shape surrounding the second contact metal 112 in a plan view. An inner diameter side of the second contact metal 112 constitutes an emission port.

The bottom surface and side surfaces (specifically, inside and outside side surfaces that oppose each other) of the trench T and the upper surface of the second contact layer 109 are covered by an insulating film 110. The insulating film 110 has a first contact hole 110a that opens on the first contact metal 113 and a second contact hole 110b that opens on the second contact metal 112. First and second pad metals 114 and 111 are provided on the insulating film 110. As an example, the first pad metal 114 constitutes a cathode electrode (n-side electrode) together with the first contact metal 113. As an example, the second pad metal 111 constitutes an anode electrode (p-side electrode) together with the second contact metal 112.

The first pad metal 114 has a contact portion 114a that comes into contact with the first contact metal 113 through the first contact hole 110a, a rising portion 114b that is connected to the contact portion 114a at one end and rises up to the opening of the trench T along the outside side surface of the trench T, an extending portion 114c that is connected to another end of the rising portion 114b at one end and extends away from the second contact metal 112 along the upper surface of the second contact layer 109, and a pad portion 114d that is connected to another end of the extending portion 114c.

The second pad metal 111 has a contact portion 111a that comes into contact with the second contact metal 112 through the second contact hole 110b, an extending portion 111b that is connected to the contact portion 111a at one end and extends away from the pad portion 114d of the first pad metal 114 along the upper surface of the second contact layer 109, and a pad portion 111c that is connected to another end of the extending portion 111b. The contact portion 111a has a ring shape along the second contact metal 112.

As an example, the resonator R further includes an ion implantation area IIA as a current constriction area arranged between a surface of the first reflecting structure 102 on an opposite side (lower side) to a side of the active layer 106 and a surface of the second reflecting structure 108 on an opposite side (upper side) to a side of the active layer 106. As an example, the ion implantation area IIA is formed in a circumferential shape (for example, an annular shape) along an outer periphery of the trench T in a plan view so as to straddle the first contact layer 104, the first cladding layer 105, the active layer 106, and the second cladding layer 107. Although the ion implantation area IIA is not essential in the surface-emitting laser 10, for practical purposes, the ion implantation area IIA is preferably provided to improve efficiency.

### [Substrate]

The substrate 101 is constituted of, as an example, an i-type (insulating) or semi-insulating semiconductor substrate (for example, an i-GaAs substrate).

### [First Reflecting Structure]

The first reflecting structure 102 is, as an example, a semiconductor multilayer reflector. A multilayer reflector is also referred to as a distributed Bragg reflector (DBR). More specifically, as an example, the first reflecting structure 102 is an i-type semiconductor multilayer reflector having a structure in which a plurality of (for example, two) types of semiconductor layers with refractive indices that differ from each other are alternately stacked with an optical thickness of ¼ wavelength of an oscillation wavelength. The first reflecting structure 102 is constituted of an i-type AlGaAs-based compound semiconductor (for example, i-GaAs/AlGaAs). A reflectance of the first reflecting structure 102 is set slightly higher than a reflectance of the second reflecting structure 108. The first reflecting structure 102 is also referred to as a lower reflector. The first reflecting structure 102 is a high-refractive index layer (for example, an i-GaAs layer) of which an uppermost layer 102a is thicker than other refractive index layers. As an example, the first reflecting structure 102 has a reflectance of 90% or higher (preferably 93% or higher, more preferably 96% or higher, and even more preferably 99% or higher) relative to the oscillation wavelength of the surface-emitting laser 10.

### [Outline of Metasurface]

The metasurface 103 has a light-trapping structure that traps light in an in-plane direction (transverse direction) using a difference in effective refractive indices. Details of the metasurface 103 will be described later.

### [First Contact Layer]

The first contact layer 104 is constituted of, for example, an n-type GaAs layer (n-GaAs layer). The first contact layer 104 is a highly doped layer in which an n-type impurity (for example, Si, Se, or Te) is doped in a high concentration.

### [First Cladding Layer]

The first cladding layer 105 is constituted of, for example, an n-type AlGaAs-based compound semiconductor. The first cladding layer 105 is also referred to as a lower cladding layer or a lower spacer layer.

### [Active Layer]

As an example, the active layer 106 has a quantum well structure constituted of a GaAs-based compound semiconductor (for example, InGaAs) and including a barrier layer and a quantum well layer. The quantum well structure may be a single quantum well structure (QW structure) or a multiple quantum well structure (MQW structure). In the active layer 106, as an example, an area surrounded by the ion implantation area IIA is a light emission area (current injection area). Note that the active layer 106 may have a plurality of QW structures or a plurality of MQW structures stacked via tunnel junctions or, in other words, a multi-junction structure. In addition, the active layer 106 may have a quantum dot (QD) structure.

### [Second Cladding Layer]

The second cladding layer 107 is constituted of, for example, a p-type AlGaAs-based compound semiconductor. The second cladding layer 107 is also referred to as an upper cladding layer or an upper spacer layer.

### [Second Reflecting Structure]

The second reflecting structure 108 is, as an example, a semiconductor multilayer reflector. A multilayer reflector is also referred to as a distributed Bragg reflector (DBR). More specifically, as an example, the second reflecting structure 108 is a p-type semiconductor multilayer reflector having a structure in which a plurality of (for example, two) types of semiconductor layers with refractive indices that differ from each other are alternately stacked with an optical thickness of ¼ wavelength of an oscillation wavelength. The second reflecting structure 108 is constituted of a p-type AlGaAs-based compound semiconductor (for example, p-GaAs/AlGaAs). The second reflecting structure 108 is also referred to as a lower reflector. As an example, the second reflecting structure 108 has a reflectance of 90% or higher (preferably 93% or higher, more preferably 96% or higher, and even more preferably 99% or higher) relative to the oscillation wavelength of the surface-emitting laser 10.

### [Second Contact Layer]

The second contact layer 109 is constituted of, for example, a p-type GaAs layer (p-GaAs layer). The second contact layer 109 is a highly doped layer in which a p-type impurity (for example, Mg, Zn, P, or C) is doped in a high concentration.

### [Insulating Film]

The insulating film 110 is constituted of, for example, a dielectric body such as SiO₂, SiN, or SiON.

### [Anode Electrode]

Each of the second contact metal 112 and the second pad metal 111 that constitute the anode electrode is constituted of, for example, Ti/Pt/Au. In the second pad metal 111, for example, the pad portion 111c is connected to an anode side of a laser driver via a bonding wire.

### [Cathode Electrode]

Each of the first contact metal 113 and the first pad metal 114 that constitute the cathode electrode is constituted of, for example, Ti/Pt/Au. In the first pad metal 114, for example, the pad portion 114d is connected to a cathode side of the laser driver via a bonding wire.

### [Details of Metasurface]

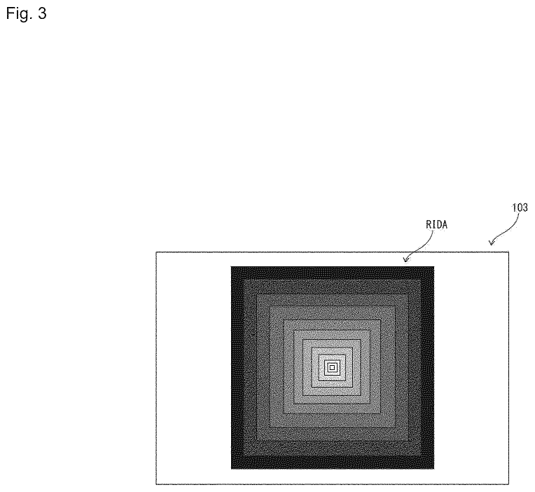

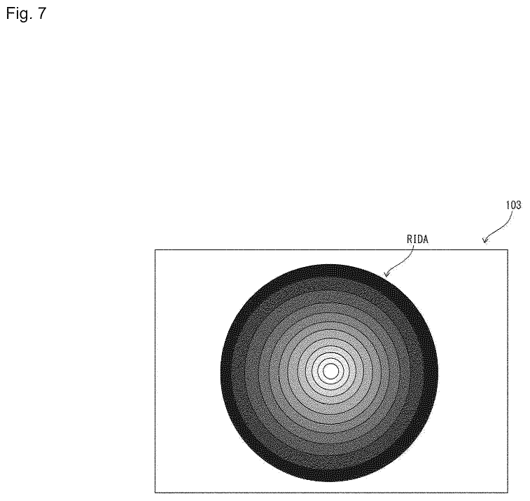

The metasurface 103 can change an amount of phase change with respect to transmitted light (specifically, light from the active layer 106) depending on an arrangement of unit structures of the metasurface 103. When the metasurface 103 is present in the resonator R, the effective refractive index of the resonator R is highly dependent on a design of the metasurface 103. Taking advantage of this fact, the effective refractive index can be changed in the in-plane direction (transverse direction) by changing the design of the metasurface 103 in the in-plane direction and, accordingly, an effective refractive index distribution for trapping light can be formed in the in-plane direction (transverse direction). The metasurface 103 has an effective refractive index distribution area RIDA that has the effective refractive index distribution (for example, refer to FIGS. 3 and 7). A metasurface is also referred to as a meta-structure layer.

As an example, the metasurface 103 is arranged between an i-GaAs layer that is the uppermost layer 102a of the first reflecting structure 102 and the first contact layer 104.

The effective refractive index distribution area RIDA is more preferably provided in an area corresponding to an area corresponding to at least the light emission area of the active layer 106 (for example, an area surrounded by the ion implantation area IIA as a current constriction area) in the metasurface 103.

The metasurface 103 has a plurality of unit structures 103a two-dimensionally arranged in the in-plane direction. Each unit structure 103a is also referred to as a meta-atom. Each unit structure 103a is preferably smaller than the oscillation wavelength of the surface-emitting laser 10. In this case, scattering loss due to periodicity of arrangement can be suppressed and more reliable light trapping can be achieved.

The plurality of unit structures 103a are arranged at a position (in this case, below the first contact layer 104) deviated from a current pathway during driving (current pathway from the anode electrode to the cathode electrode) in the resonator R. Accordingly, an increase in resistance can be suppressed.

The effective refractive index distribution is determined by a material, a shape, a size, and an arrangement of each unit structure 103a and a material of a second area A2. The material, the shape, the size, and the arrangement of each unit structure 103a and the material of the second area A2 that determine the effective refractive index distribution are set so as to trap light due to a difference in effective refractive indices. Furthermore, the metasurface 103 is set not to form a stopband at the oscillation wavelength of the surface-emitting laser 10 with respect to light propagating in the in-plane direction. In this respect, the metasurface 103 is demarcated from, for example, a photonic crystal structure (PCS).

The metasurface 103 can be fabricated using, for example, lithographic techniques with a resolution of 1 μm or less such as electron beam lithography, optical lithography, nanoimprinting, and ion beam exposure techniques and dry etching (for example, ICP-RIE: Inductively Coupled Plasma-Reactive Ion Etching).

### (Example of Refractive Index Distribution)

FIG. 3 is a diagram schematically showing an example of an effective refractive index distribution in the in-plane direction of the metasurface 103 of the surface-emitting laser 10 according to the first embodiment of the present technique. FIG. 3 shows that lighter colored areas have a higher effective refractive index and darker colored areas have a lower effective refractive index. The effective refractive index distribution area RIDA of the metasurface 103 shown in FIG. 3 is an area in which an effective refractive index gradually decreases from a reference point (for example, a center) to an outer edge side in the in-plane direction. In other words, the effective refractive index distribution area RIDA of the metasurface 103 shown in FIG. 3 is an area in which an effective refractive index decreases in a plurality of stages (for example, multiple stages) from a reference point RP (for example, a center) to an outer edge side in the in-plane direction. More specifically, in the effective refractive index distribution area RIDA shown in FIG. 3, a plurality of areas with quadrangular-shaped frames with different effective refractive indices and sizes (however, an innermost area has a quadrangular shape) are adjacent to each other in inward/outward directions, with a more inward area having a higher effective refractive index (a more outward area having a lower effective refractive index). Note that the reference point RP need not coincide with a center of the metasurface 103 or a center of the effective refractive index distribution area RIDA.

The effective refractive index distribution area RIDA in FIG. 3 has an effective refractive index distribution similar to a graded index with a lensing action in which an overall effective refractive index change between adjacent areas is relatively gradual and continuous. Accordingly, a light-trapping structure with small scattering loss can be realized.

### (Unit Structure Arrangement Example 1)

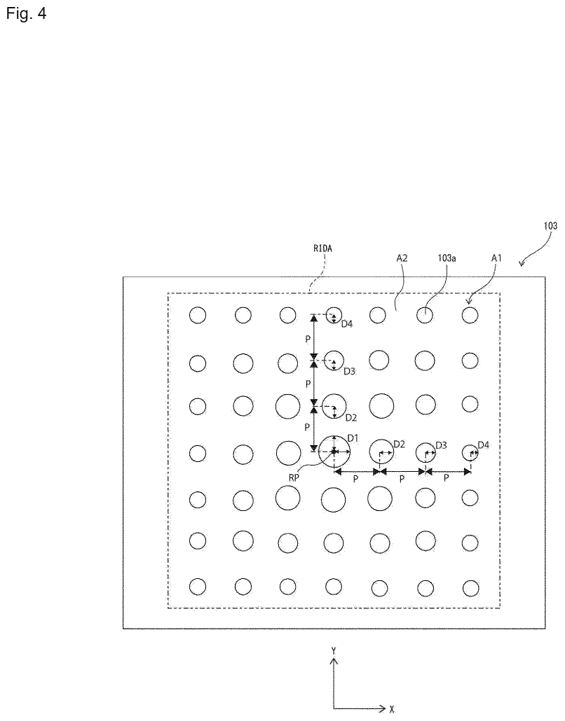

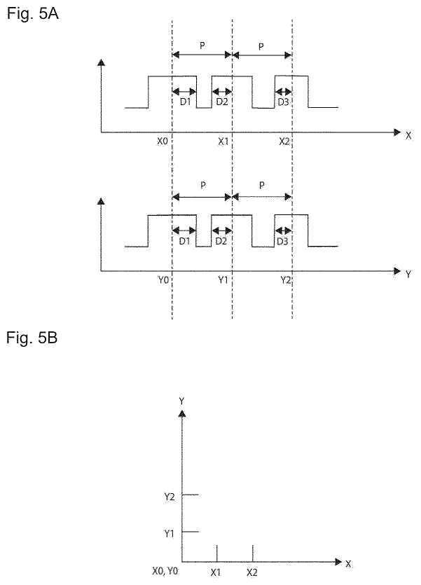

FIG. 4 is a diagram showing arrangement example 1 of a plurality of unit structures of the metasurface 103 of the surface-emitting laser according to the first embodiment of the present technique. FIGS. 5A and 5B are each a diagram for describing arrangement example 1 of the plurality of unit structures 103a of the metasurface 103 of the surface-emitting laser 10 according to the first embodiment of the present technique.

The metasurface 103 shown in FIG. 4 has a first area A1 including the plurality of unit structures 103a aligned in the in-plane direction and a second area A2 surrounding each of the plurality of unit structures 103a and having a different material refractive index from the first area A1. In this case, the first area A1 is constituted of a plurality of unit structures 103a.

A material refractive index difference Δn between the first and second areas A1 and A2 is preferably high. For example, one of the first and second areas A1 and A2 may be a gas (for example, air or an inert gas) or a vacuum and the other may be a dielectric body (for example, SiO₂, SiN, SiON, a-Si, or a polyimide) or a semiconductor (for example, GaAs or AlGaAs). For example, one of the first and second areas A1 and A2 may be a dielectric body (for example, SiO₂, SiN, or SiON) and the other may be a semiconductor (for example, GaAs or AlGaAs). For example, both of the first and second areas A1 and A2 may be a dielectric body (for example, SiO₂, SiN, SiON, a-Si, or a polyimide). The dielectric body may be, for example, an inorganic polymer or an organic polymer. For example, both of the first and second areas A1 and A2 may be a semiconductor (for example, GaAs or AlGaAs).

In the surface-emitting laser 10, as an example, one of the first and second areas A1 and A2 can be i-GaAs and the other a gas (for example, air) or a vacuum.

The plurality of unit structures 103a are arranged, as an example, at a predetermined pitch P in the in-plane direction. The pitch P is preferably shorter than the emission wavelength of the active layer 106. Accordingly, scattering loss resulting from periodicity of arrangement can be suppressed. On the metasurface 103, a duty ratio (Dn+D(n+1))/P that is a ratio of a sum (Dn+D(n+1)) of ½ (denoted by Dk, where k is a natural number) of widths of each of two adjacent unit structures 103a to the pitch P (a ratio of the unit structures 103a to the pitch P or, in other words, a proportion of the unit structures 103a in the pitch P) varies in the in-plane direction. In this case, Dk refers to ½ of a width of any unit structure 103a at a predetermined position (for example, an upper end, a lower end, or midway between the upper end and the lower end of the unit structure 103a) in a thickness direction of the metasurface 103.

In the example shown in FIG. 4, the first area A1 has a higher material refractive index than the second area A2, and the duty ratio (Dn+D(n+1)/P gradually decreases from the reference point RP (for example, the center) to an outer edge side in the in-plane direction. In other words, in the example shown in FIG. 4, the first area A1 has a higher material refractive index than the second area A2, and the duty ratio (Dn+D(n+1)/P decreases in a plurality of stages from the reference point (for example, the center) to an outer edge side in the in-plane direction. Here, while the duty ratio (Dn+D(n+1)/P is reduced in three stages (D1>D2>D3>D4) in each of an X-axis direction and a Y-axis direction for the sake of convenience, the reduction of the duty ratio (Dn+D(n+1)/P is not limited thereto and may be reduced in more or fewer stages.

Specifically, when an XY two-dimensional coordinate system with the reference point RP (for example, the center) of the effective refractive index distribution area RIDA as an origin (X0, Y0) is set in the in-plane direction on the metasurface 103 as shown in FIGS. 4 and 5B, the duty ratio (Dn+D(n+1)/P of the metasurface 103 in the X-axis direction may be gradually (in a plurality of steps) reduced in the +X direction from the reference point (X0, Y0) in the order of (D1+D2)/P and (D2+D3)/P (where D1>D2>D3) as shown in FIG. 5A (the same applies to the −X direction). Similarly, the duty ratio (Dn+D(n+1)/P of the metasurface 103 in the Y-axis direction may be gradually (in a plurality of steps) reduced in the +Y direction from the reference point (X0, Y0) in the order of (D1+D2)/P and (D2+D3)/P (where D1>D2>D3) as shown in FIG. 5A (the same applies to the −Y direction). In this manner, the effective refractive index can be gradually (in a plurality of stages) reduced from the reference point RP to outer edge sides (+X side, −X side, +Y side, and −Y side).

### (Unit Structure Arrangement Example 2)

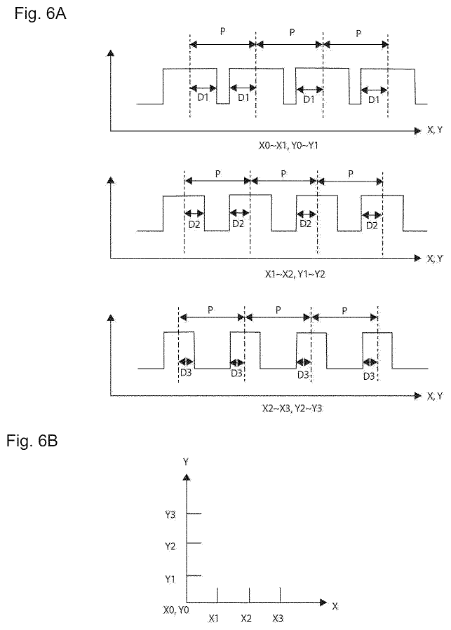

FIGS. 6A and 6B are each a diagram for describing arrangement example 2 of the plurality of unit structures 103a of the metasurface 103 of the surface-emitting laser according to the first embodiment of the present technique. As shown in FIG. 6B, when an XY two-dimensional coordinate system with the reference point RP (for example, the center) of the effective refractive index distribution area RIDA as an origin (X0, Y0) is set in the in-plane direction on the metasurface 103, the duty ratio (Dn+D(n+1)/P of the metasurface 103 in the X-axis direction may be gradually (in a plurality of stages per section) reduced in the +X direction so that a same duty ratio (D1+D1)/P occurs consecutively a plurality of times in a section from X0 to X1, a same duty ratio (D2+D2)/P occurs consecutively a plurality of times in a section from X1 to X2, and a same duty ratio (D3+D3)/P occurs consecutively a plurality of times in a section from X2 to X3 (where D1>D2>D3) as shown in FIG. 6A (the same applies to the −X direction). Similarly, the duty ratio (Dn+D(n+1)/P of the metasurface 103 in the Y-axis direction may be gradually (in a plurality of stages per section) reduced in the +Y direction so that a same duty ratio (D1+D1)/P occurs consecutively a plurality of times in a section from Y0 to Y1, a same duty ratio (D2+D2)/P occurs consecutively a plurality of times in a section from Y1 to Y2, and a same duty ratio (D3+D3)/P occurs consecutively a plurality of times in a section from Y2 to Y3 (where D1>D2>D3) as shown in FIG. 6A (the same applies to the −Y direction). In this manner, the effective refractive index can be gradually (in a plurality of stages) reduced from the reference point RP to outer edge sides (+X side, −X side, +Y side, and −Y side).

Note that in the metasurface 103, a configuration in which the material refractive index of the first area A1 is lower than that of the second area A2 can also be adopted. In this case, in the metasurface 103, the duty ratio (Dn+D(n+1)/P need only gradually (in a plurality of stages) increase from the reference point RP (for example, the center) to an outer edge side in the in-plane direction. Accordingly, in the metasurface 103, the effective refractive index can be gradually (in a plurality of stages) reduced from the reference point RP to the outer edge side in the in-plane direction. Specifically, the plurality of unit structures 103a may be arranged so that, for example, D1<D2<D3<D4 is satisfied in FIG. 4 and D1<D2<D3 is satisfied in FIGS. 5A and 6A.

### (Another Example of Refractive Index Distribution)

FIG. 7 is a diagram schematically showing another example of the effective refractive index distribution in the in-plane direction of the metasurface 103 of the surface-emitting laser 10 according to the first embodiment of the present technique. FIG. 7 shows that lighter colored areas have a higher effective refractive index and darker colored areas have a lower effective refractive index. The effective refractive index distribution area RIDA of the metasurface 103 shown in FIG. 7 is an area in which an effective refractive index gradually decreases from a reference point (for example, a center) to an outer edge side in the in-plane direction. In other words, the effective refractive index distribution area IRDA of the metasurface 103 shown in FIG. 7 is an area in which an effective refractive index decreases in a plurality of stages (for example, multiple stages) from a reference point (for example, a center) to an outer edge side in the in-plane direction. More specifically, in the effective refractive index distribution area RIDA shown in FIG. 7, a plurality of areas with annular-shaped frames with different effective refractive indices and sizes (however, an innermost area has a circular shape) are adjacent to each other in inward/outward directions, with a more inward area having a higher effective refractive index (a more outward area having a lower effective refractive index). Note that the reference point RP need not coincide with a center of the metasurface 103 or a center of the effective refractive index distribution area RIDA.

The effective refractive index distribution area RIDA in FIG. 7 also has an effective refractive index distribution similar to a graded index in which an overall effective refractive index change between adjacent areas is relatively gradual and continuous, and light incident to the effective refractive index distribution area RIDA is trapped in the effective refractive index distribution area RIDA according to a principle similar to that of the effective refractive index distribution area RIDA in FIG. 3.

### (Unit Structure Arrangement Example 3)

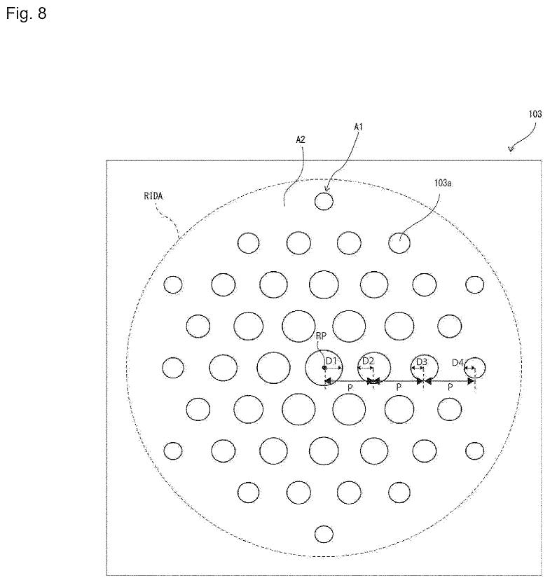

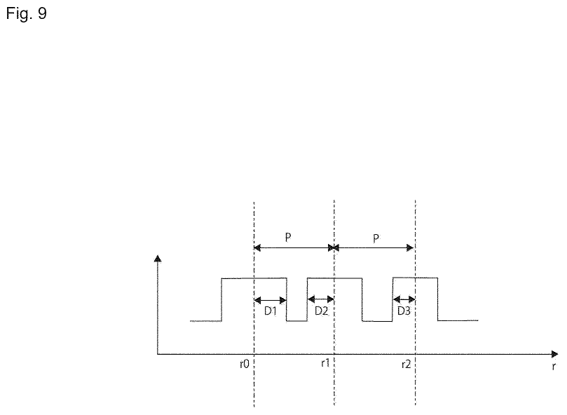

FIG. 8 is a diagram showing arrangement example 3 of a plurality of unit structures of the metasurface 103 of the surface-emitting laser according to the first embodiment of the present technique. FIG. 9 is a diagram for describing arrangement example 3 of the plurality of unit structures 103a of the metasurface 103 of the surface-emitting laser 10 according to the first embodiment of the present technique.

The metasurface 103 shown in FIG. 8 has a first area A1 including the plurality of unit structures 103a aligned in the in-plane direction and a second area A2 surrounding each of the plurality of unit structures 103a and having a different material refractive index from the first area A1. In this case, the first area A1 is constituted of a plurality of unit structures 103a.

The plurality of unit structures 103a are arranged at a predetermined pitch P in the in-plane direction. A duty ratio (Dn+D(n+1))/P that is a ratio of a sum (Dn+D(n+1)) of ½ (denoted by Dk, where k is a natural number) of widths of the unit structures 103a to the pitch P (a ratio of the unit structures 103a to the pitch P or, in other words, a proportion of the unit structures 103a in the pitch P) varies in the in-plane direction. In this case, Dk refers to ½ of a width of any unit structure 103a at a predetermined position (for example, an upper end, a lower end, or midway between the upper end and the lower end of the unit structure 103a) in a thickness direction of the metasurface 103.

In the example shown in FIG. 8, the first area A1 has a higher material refractive index than the second area A2, and the duty ratio (Dn+D(n+1))/P gradually decreases from the reference point RP (for example, the center) to an outer edge side in the in-plane direction. In other words, in the example shown in FIG. 8, the first area A1 has a higher material refractive index than the second area A2, and the duty ratio (Dn+D(n+1))/P decreases in a plurality of stages from the reference point (for example, the center) to an outer edge side in the in-plane direction. Here, while the duty ratio (Dn+D(n+1))/P is reduced in three stages (D1>D2>D3>D4) from the reference point RP for the sake of convenience, the reduction of the duty ratio (Dn+D(n+1))/P is not limited thereto and may be reduced in more or fewer stages.

Specifically, when a radial direction r that extends radially along the in-plane direction from the reference point RP (for example, the center) of the effective refractive index distribution area (RIDA) is set in the in-plane direction on the metasurface 103, the duty ratio (Dn+D(n+1))/P of the effective refractive index distribution area RIDA may be gradually (in a plurality of stages) reduced so as to assume (D1+D2)/P between r0 and r1 and (D2+D3)/P between r1 and r2 (where D1>D2>D3) when the reference point RP (for example the center) of the effective refractive index distribution area RIDA is r0 as shown in FIG. 9.

### (Unit Structure Arrangement Example 4)

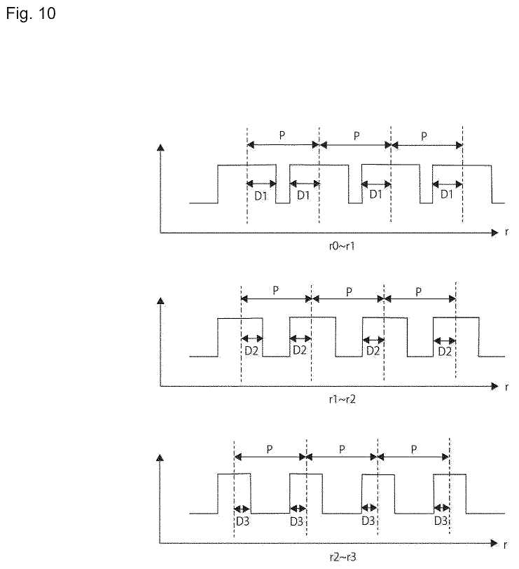

FIG. 10 is a diagram for describing arrangement example 4 of the plurality of unit structures 103a of the metasurface 103 of the surface-emitting laser according to the first embodiment of the present technique. As shown in FIG. 10, when a radial direction r that extends radially along the in-plane direction from the reference point RP (for example, the center) of the effective refractive index distribution area (RIDA) is set on the metasurface 103, the duty ratio (Dn+D(n+1))/P of the effective refractive index distribution area RIDA may be gradually (in a plurality of stages per section) reduced so that a same duty ratio (D1+D1)/P occurs consecutively a plurality of times in a section from r0 to r1, a same duty ratio (D2+D2)/P occurs consecutively a plurality of times in a section from r1 to r2, and a same duty ratio (D3+D3)/P occurs consecutively a plurality of times in a section from r2 to r3 (where D1>D2>D3), when the reference point RP of the effective refractive index distribution area RIDA is r0.

Note that in the metasurface 103, a configuration in which the material refractive index of the first area A1 is lower than that of the second area A2 can also be adopted. In this case, in the metasurface 103, the duty ratio (Dn+D(n+1))/P need only gradually (in a plurality of stages) increase from the reference point RP (for example, the center) to an outer edge side in the in-plane direction. Accordingly, in the metasurface 103, the effective refractive index can be gradually (in a plurality of stages) reduced from the reference point RP to the outer edge side in the in-plane direction. Specifically, the plurality of unit structures 103a may be arranged so that, for example, D1<D2<D3<D4 is satisfied in FIG. 8 and D1<D2<D3 is satisfied in FIGS. 9 and 10.

### (Configuration Example of Unit Structure)

In the metasurface 103, in order to form the effective refractive index distribution area RIDA in which the effective refractive index gradually (in a plurality of stages) decreases from the reference point RP (for example, the center) to an outer edge side, a shape in a plan view (transverse cross-sectional shape) of the unit structure 103a is preferably a shape with two-fold symmetry or a shape with N-fold symmetry (N≥3).

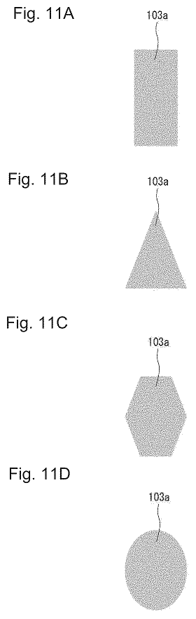

FIGS. 11A to 11D are each a plan view of each of configuration examples 1 to 4 of the unit structure 103a of the metasurface 103 of the surface-emitting laser 10 according to the first embodiment of the present technique. Configuration examples 1 to 4 of the unit structure 103a each have a shape in a plan view (transverse cross-sectional shape) with two-fold symmetry. In configuration example 1 shown in FIG. 11A, the unit structure 103a has a rectangular shape in a plan view. In configuration example 2 shown in FIG. 11B, the unit structure 103a has a shape of an isosceles triangle in a plan view. In configuration example 3 shown in FIG. 11C, the unit structure 103a has a shape in a plan view of a hexagon created by stretching a regular hexagon in one direction. In configuration example 4 shown in FIG. 11D, the unit structure 103a has an elliptical shape in a plan view. In configuration examples 1 to 4 shown in FIGS. 11A to 11D, the unit structure 103a is shape anisotropic and polarization dependent. Therefore, when each of the plurality of unit structures 103a has the same shape anisotropy (for example, when each unit structure 103a has a shape for which a same direction is a longitudinal direction or a transverse direction), the unit structures 103a will have polarization dependency in the same direction and can exhibit a polarization control function of emitted light. Note that the shape in a plan view (transverse cross-sectional shape) of the unit structure 103a may be a polygonal shape other than a hexagonal shape.

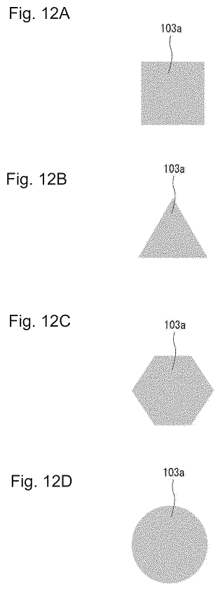

FIGS. 12A to 12D are each a plan view of each of configuration examples 5 to 8 of the unit structure of the metasurface 103 of the surface-emitting laser 10 according to the first embodiment of the present technique. Configuration examples 5 to 8 of the unit structure 103a each have a shape in a plan view (transverse cross-sectional shape) with N-fold (N≥3, for example, 3-fold symmetry). In configuration example 5 shown in FIG. 12A, the unit structure 103a has a square shape in a plan view. In configuration example 6 shown in FIG. 12B, the unit structure 103a has a shape of an equilateral triangle in a plan view. In configuration example 7 shown in FIG. 12C, the unit structure 103a has a shape of a regular hexagon in a plan view. In configuration example 8 shown in FIG. 12D, the unit structure 103a has a circular shape in a plan view. Note that the shape in a plan view (transverse cross-sectional shape) of the unit structure 103a may be a regular polygon other than a regular hexagon.

The shape in a plan view (transverse cross-sectional shape) of each unit structure 103a of the metasurface 103 is not limited to the general shapes described above and may also be a special shape as described below.

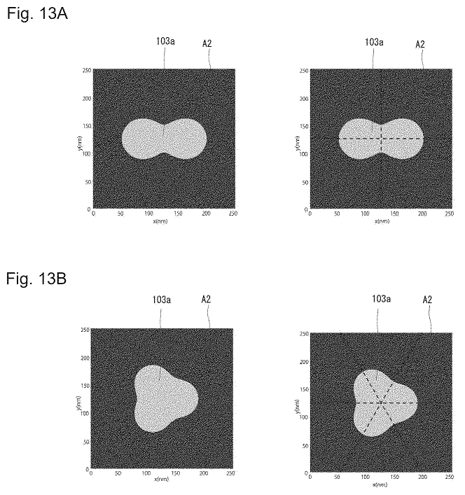

FIGS. 13A and 13B are each a plan view of each of configuration examples 9 and 10 of the unit structure 103a of the metasurface 103 of the surface-emitting laser 10 according to the first embodiment of the present technique. In configuration examples 9 and 10, either one of the unit structure 103a and the second area A2 is a semiconductor and the other a dielectric body or both the unit structure 103a and the second area A2 are dielectric bodies.

The shape in a plan view (transverse cross-sectional shape) of each unit structure 103a of the metasurface 103 may be, for example, a peanut shape with a constricted central part like configuration example 9 shown in a left diagram in FIG. 13A. The peanut shape of configuration example 9 has two-fold symmetry as shown in a right diagram in FIG. 13A (each of two orthogonal dashed lines is an axis of symmetry).

The shape in a plan view (transverse cross-sectional shape) of each unit structure 103a of the metasurface 103 may be, for example, a flower petal shape that is convex on three sides like configuration example 10 shown in a left diagram in FIG. 13B. The flower petal shape of configuration example 10 has three-fold symmetry as shown in a right diagram in FIG. 13B (each of three intersecting dashed lines is an axis of symmetry).

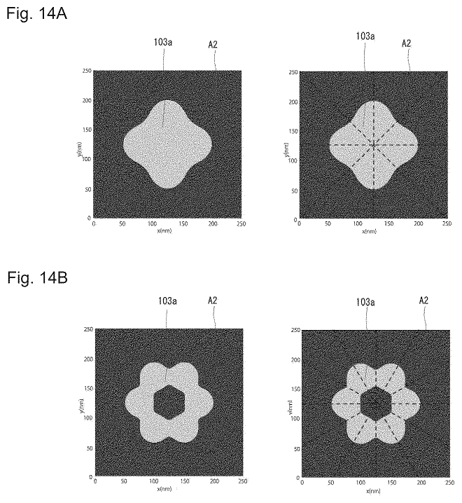

FIGS. 14A and 14B are each a plan view of each of configuration examples 11 and 12 of the unit structure 103a of the metasurface 103 of the surface-emitting laser 10 according to the first embodiment of the present technique. In configuration examples 11 and 12, either one of the unit structure 103a and the second area A2 is a semiconductor and the other a dielectric body or both the unit structure 103a and the second area A2 are dielectric bodies.

The shape in a plan view (transverse cross-sectional shape) of each unit structure 103a of the metasurface 103 may be, for example, a flower petal shape that is convex on four sides like configuration example 11 shown in a left diagram in FIG. 14A. The flower petal shape of configuration example 11 has four-fold symmetry as shown in a right diagram in FIG. 14A (each of four intersecting dashed lines is an axis of symmetry).

The shape in a plan view (transverse cross-sectional shape) of each unit structure 103a of the metasurface 103 may be, for example, a flower petal shape that is convex on six sides like configuration example 12 shown in a left diagram in FIG. 14B. The flower petal shape of configuration example 12 has six-fold symmetry as shown in a right diagram in FIG. 14B (each of six intersecting dashed lines is an axis of symmetry).

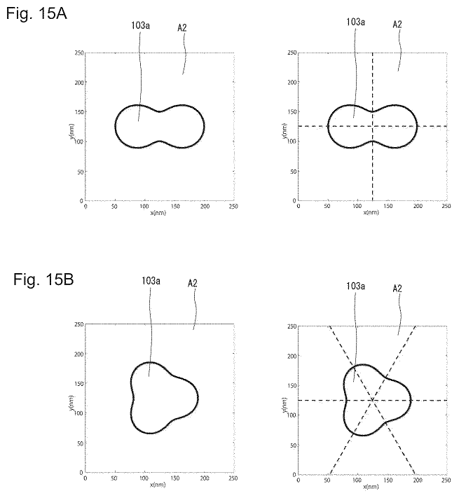

FIGS. 15A and 15B are each a plan view of each of configuration examples 13 and 14 of the unit structure 103a of the metasurface 103 of the surface-emitting laser 10 according to the first embodiment of the present technique. In configurations 13 and 14, one of the unit structure 103a and the second area A2 is a gas or a vacuum and the other is a dielectric body or a semiconductor.

The shape in a plan view (transverse cross-sectional shape) of each unit structure 103a of the metasurface 103 may be, for example, a peanut shape with a constricted central part like configuration example 13 shown in a left diagram in FIG. 15A. The peanut shape of configuration example 13 has two-fold symmetry as shown in a right diagram in FIG. 15A (each of two orthogonal dashed lines is an axis of symmetry).

The shape in a plan view (transverse cross-sectional shape) of each unit structure 103a of the metasurface 103 may be, for example, a flower petal shape that is convex on three sides like configuration example 14 shown in a left diagram in FIG. 15B. The flower petal shape of configuration example 14 has three-fold symmetry as shown in a right diagram in FIG. 14B (each of three intersecting dashed lines is an axis of symmetry).

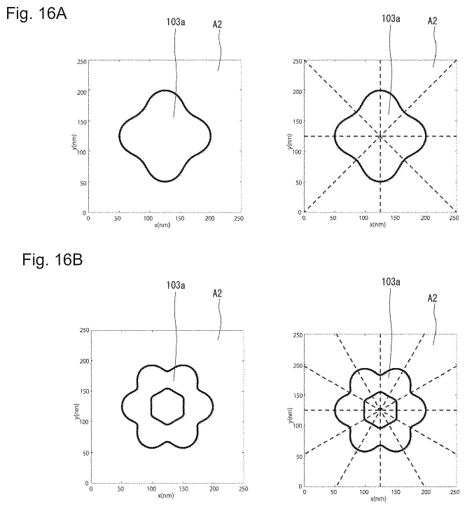

FIGS. 16A and 16B are each a plan view of each of configuration examples 15 and 16 of the unit structure 103a of the metasurface 103 of the surface-emitting laser 10 according to the first embodiment of the present technique. In configuration examples 15 and 16, one of the unit structure 103a and the second area A2 is a gas or a vacuum and the other is a dielectric body or a semiconductor.

The shape in a plan view (transverse cross-sectional shape) of each unit structure 103a of the metasurface 103 may be, for example, a flower petal shape that is convex on four sides like configuration example 15 shown in a left diagram in FIG. 16A. The flower petal shape of configuration example 15 has four-fold symmetry as shown in a right diagram in FIG. 15A (each of four intersecting dashed lines is an axis of symmetry).

The shape in a plan view (transverse cross-sectional shape) of each unit structure 103a of the metasurface 103 may be, for example, a flower petal shape that is convex on six sides like configuration example 16 shown in a left diagram in FIG. 16B. The flower petal shape of configuration example 16 has six-fold symmetry as shown in a right diagram in FIG. 16B (each of six intersecting dashed lines is an axis of symmetry).

In each of the configuration examples described above, a shape in a side view (longitudinal cross-sectional shape) of each of the plurality of unit structures 103a can be any of, for example, a rectangular shape, a circular shape, an elliptical shape, or a trapezoidal shape.

In each of the configuration examples described above, an upper end and a lower end of a longitudinal cross-section of each of the plurality of unit structures 103a may be arranged on a same plane.

In each of the configuration examples described above, an outer edge of a longitudinal cross-section of each of the plurality of unit structures 103a may include a curved line.

### (Arrangement Pattern of Unit Structures)

Preferably, an arrangement pattern of the plurality of unit structures 103a in the effective refractive index distribution area RIDA is a pattern with periodicity such as those described below.

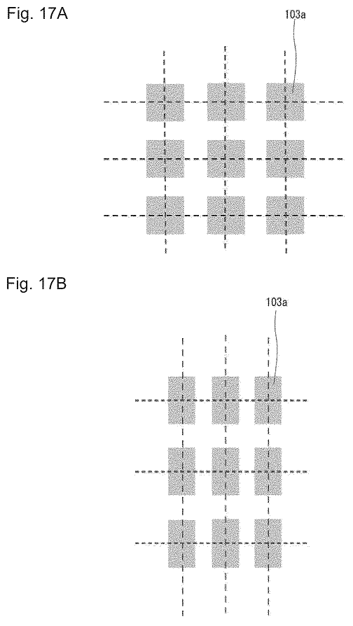

FIGS. 17A and 17B are each a plan view of each of arrangement patterns 1 and 2 of the unit structure 103a of the metasurface 103 of the surface-emitting laser 10 according to the first embodiment of the present technique. Arrangement pattern 1 shown in FIG. 17A is a pattern in which the plurality of unit structures 103a is arranged in a square lattice. Arrangement pattern 2 shown in FIG. 17B is a pattern in which the plurality of unit structures 103a is arranged in a rectangular lattice.

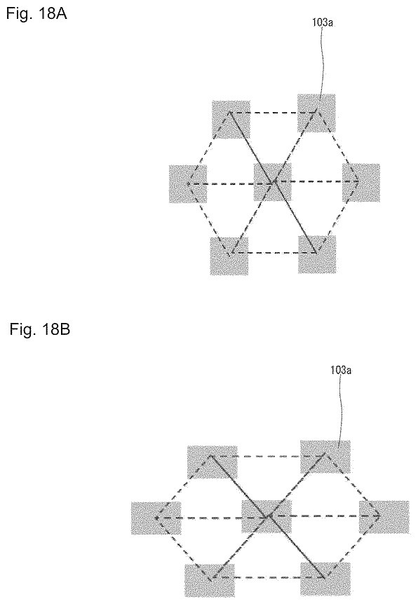

FIGS. 18A and 18B are each a plan view of each of arrangement patterns 3 and 4 of the unit structure 103a of the metasurface 103 of the surface-emitting laser 10 according to the first embodiment of the present technique. Arrangement pattern 3 shown in FIG. 18A is a pattern in which the plurality of unit structures 103a is arranged in a hexagonal lattice. Arrangement pattern 4 shown in FIG. 18B is a pattern in which the plurality of unit structures 103a is arranged in a rhombic lattice.

### <<Operation of Surface-Emitting Laser>>

Hereinafter, an operation of the surface-emitting laser 10 will be briefly described. In the surface-emitting laser 10, for example, a current supplied from the anode side of the laser driver and flowing into the resonator R from the anode electrode is constricted in the ion implantation area IIA and injected into the active layer 106 through the second contact layer 109 and the second reflecting structure 108. At this point, the active layer 106 emits light, the light travels back and forth between the first and second reflecting structures 102 and 108 while being amplified by the active layer 106 and trapped in the transverse direction by the effect of the metasurface 103, and when oscillation conditions are satisfied, the limit is emitted as laser light from an emission port on an inner diameter side of the anode electrode. The current having flowed through the active layer 106 flows through the first contact layer 104 in the transverse direction to the cathode electrode and, for example, flows out to the cathode side of the laser driver from the cathode electrode.

### <<Manufacturing Method of Surface-Emitting Laser>>

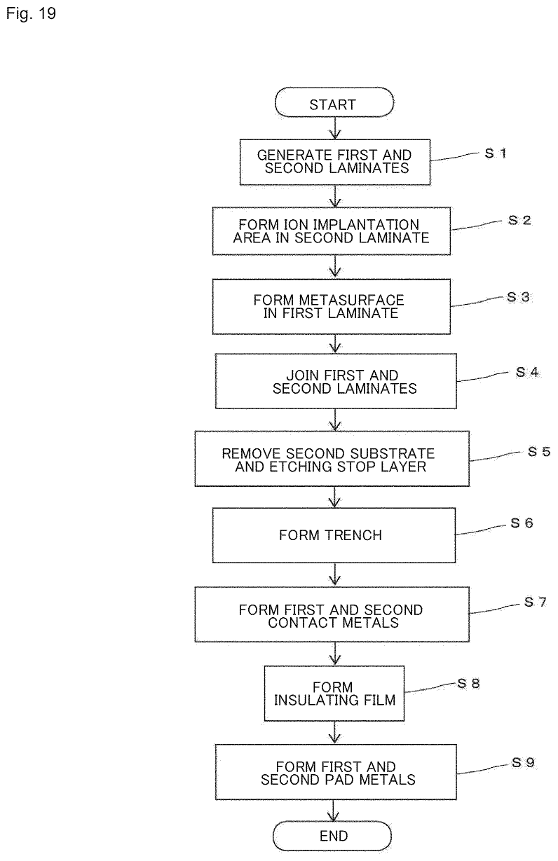

Hereinafter, a manufacturing method of the surface-emitting laser 10 will be described with reference to the flow chart shown in FIG. 19 and the like. Here, as an example, a plurality of surface-emitting lasers 10 are simultaneously generated on a single wafer (hereinafter referred to as a “substrate 101” for the sake of convenience) that is a base material of the substrate 101 by a semiconductor manufacturing method using semiconductor manufacturing equipment. Next, the plurality of surface-emitting lasers 10 that are integrated are separated from one another to obtain a plurality of chip-like surface-emitting lasers 10.

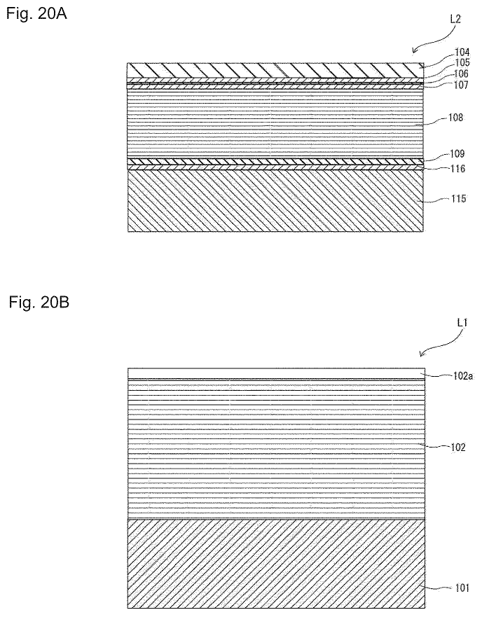

In a first step S1, first and second laminates L1 and L2 are generated. The first reflecting structure 102 (for example, i-GaAs/AlGaAs·DBR) is stacked (for example, epitaxially grown at a growth temperature of 605° C.) on the substrate 101 (a growth substrate as a first substrate) by, for example, a metal organic chemical vapor deposition (MOCVD) method to generate the first laminate L1 (refer to FIG. 20B). At this point, an i-GaAs layer that is the uppermost layer 102a of the first reflecting structure 102 is formed thick. An etching stop layer 116 (for example, an InGaP layer), the second contact layer 109, the second reflecting structure 108 (for example, p-GaAs/AlGaAs·DBR), the second cladding layer 107, the active layer 106 (for example, 3QW), the first cladding layer 105, and the first contact layer 104 are stacked (for example, epitaxially grown at a growth temperature of 605° C.) in this order on a growth substrate 115 (for example, a GaAs substrate) as a second substrate by, for example, a metal organic chemical vapor deposition (MOCVD) method to generate the second laminate L2 (refer to FIG. 20A). Note that when performing MOCVD, for example, trimethylgallium ((CH₃)₃Ga) is used as a source gas for gallium, trimethylaluminum ((CH₃)₃Al) is used as a source gas for aluminum, trimethylindium ((CH₃)₃In) is used as a source gas for indium, and trimethylarsenic ((CH₃)₃As) is used as a source gas for As, respectively. In addition, for example, monosilane (SiH₄) is used as a source gas for silicon and carbon tetrabromide (CBr₄) is used as a source gas for carbon.

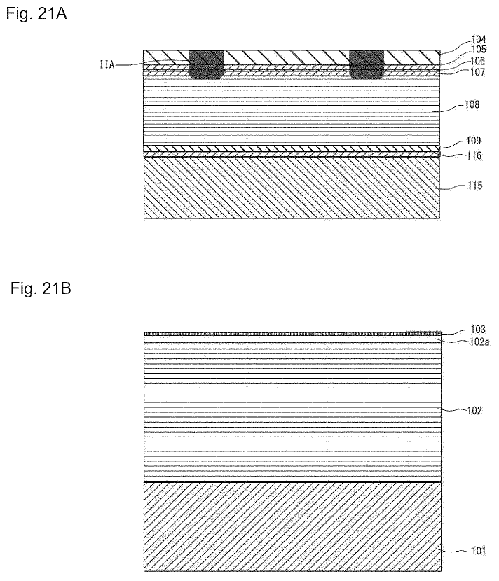

In a next step S2, the ion implantation area IIA is formed in the second laminate (refer to FIG. 21A). Specifically, photolithography is used to form a resist pattern covering an area of the second laminate other than an area where the ion implantation area IIA is to be formed and the resist pattern is used as a mask to perform ion implantation into the second laminate from the side of the first contact layer 104. An implantation depth of the ions at this point is at least until the ions reach inside the second cladding layer 107.

In step S3, the metasurface 103 is formed in the first laminate (refer to FIG. 21B). Specifically, for example, using electron beam lithography and dry etching (for example, ICP-RIE), an effective refractive index distribution area RIDA containing a plurality of unit structures 103a is formed on the surface of the uppermost layer 102a of the first reflecting structure 102. In this case, the metasurface 103 is formed so that one of the first and second areas A1 and A2 is i-GaAs and the other is air. Note that the effective refractive index distribution area RIDA may be formed over the entire area of the metasurface 103 or only in a portion (for example, a central part).

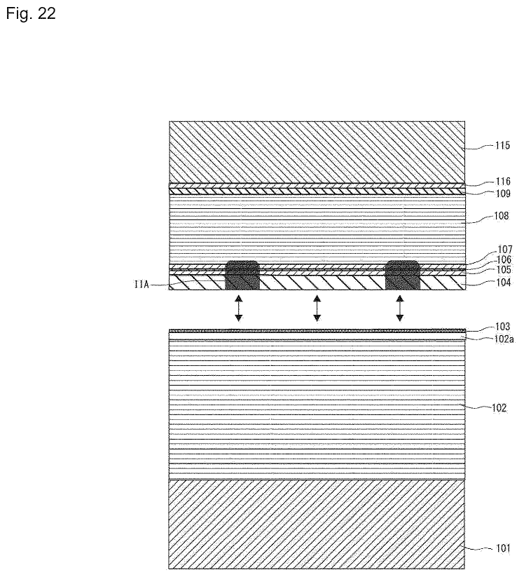

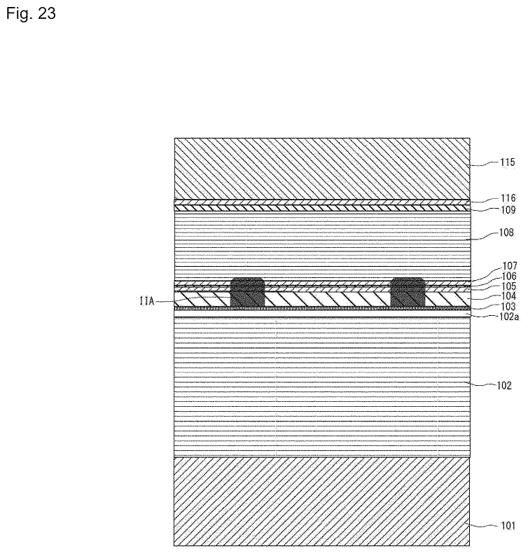

In a next step S4, the first and second laminates are joined. Specifically, a surface of the first laminate on the side of the metasurface 103 and a surface of the second laminate on the side of the first contact layer 104 are joined, for example, by surface-activated bonding (refer to FIGS. 22 and 23).

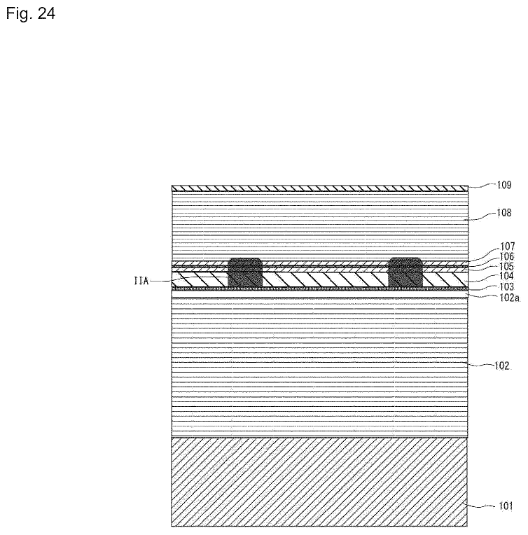

In a next step S5, the growth substrate 115 as the second substrate and the etching stop layer 116 are removed (refer to FIG. 24). Specifically, first, the growth substrate 115 as the second substrate is removed by wet etching. At this point, etching can be stopped by the etching stop layer 116. Next, the etching stop layer 116 is removed to expose the second contact layer 109.

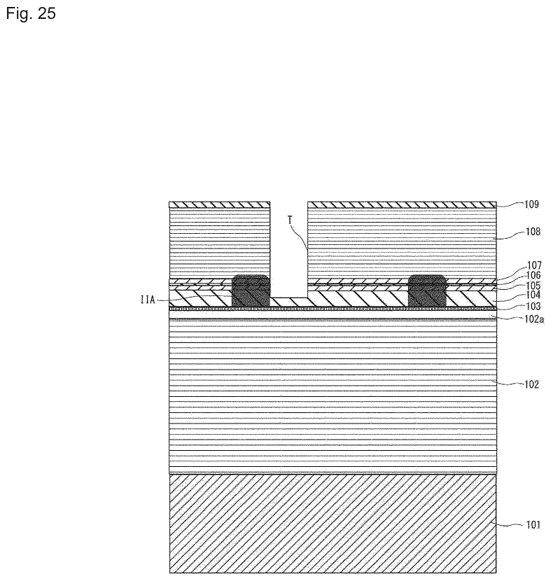

In a next step S6, a trench T is formed (refer to FIG. 25). Specifically, photolithography is used to form a resist pattern having an opening at a location where the trench T of the second laminate is to be formed and the resist pattern is used as a mask to etch the second laminate from the side of the second contact layer 109 by dry etching. The etching at this point is to be performed until an etch bottom reaches inside the first contact layer 104. Subsequently, the resist pattern is removed.

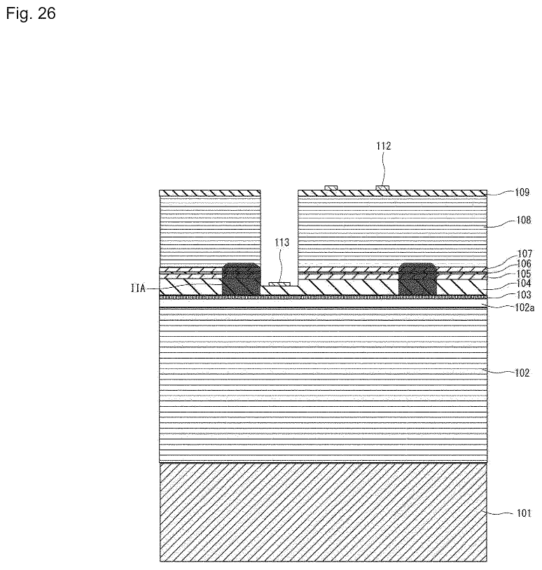

In a next step S7, the first and second contact metals 113 and 112 are formed (refer to FIG. 26). Specifically, for example, the first contact metal 113 is formed on a bottom surface of the trench T and the second contact metal 112 is formed on the second contact layer 109 using, for example, a lift-off method.

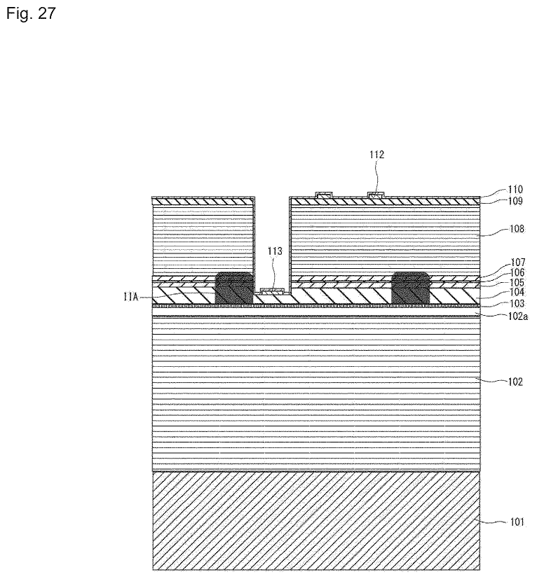

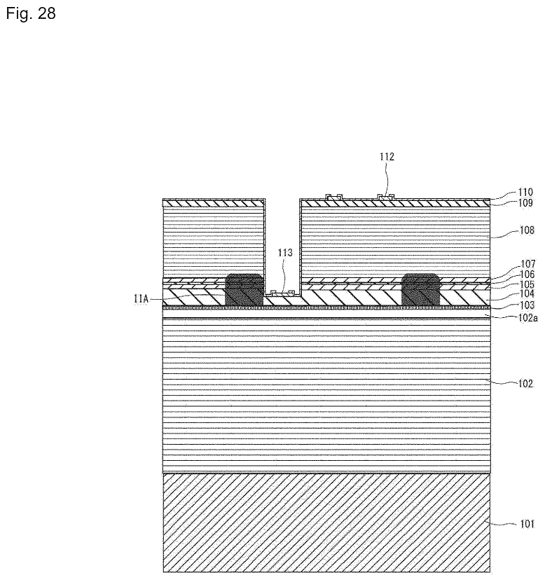

In a next step S8, the insulating film 110 is formed. Specifically, first, the insulating film 110 is deposited over the entire surface by, for example, vapor deposition or sputtering (refer to FIG. 27). Next, portions of the insulating film 110 that cover the first and second contact metals 113 and 112 are removed by photolithography and etching (refer to FIG. 28).

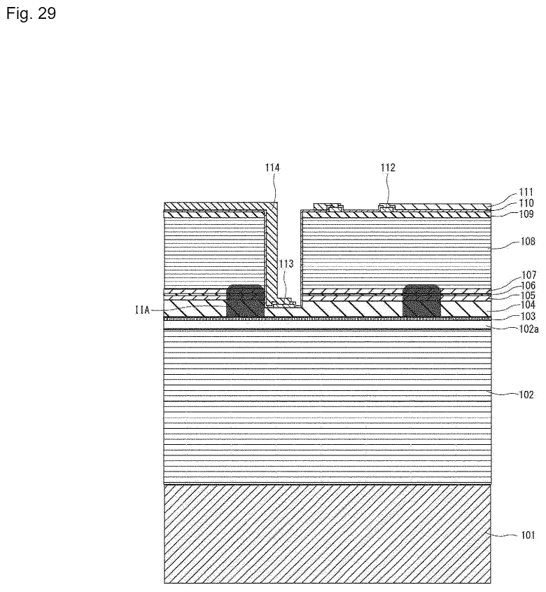

In a final step S9, the first and second pad metals 114 and 111 are formed (refer to FIG. 29). Specifically, for example, using a lift-off method, the first pad metal 114 is formed in a crank-shaped cross section so that one side portion comes into contact with the first contact metal 113 in the trench T and another side portion is located around an opening of the trench T. For example, using a lift-off method, the second pad metal 111 is formed on the insulating film 110 formed on the second contact layer 109 so as to come into contact with the second contact metal 112.

### <<Advantageous Effect of Surface-Emitting Laser>>

Hereinafter, an advantageous effect of the surface-emitting laser 10 will be described. The surface-emitting laser 10 according to the first embodiment of the present technique includes a resonator R including: first and second reflecting structures 102 and 108; and an active layer 106 arranged between the first and second reflecting structures 102 and 108. The resonator R includes, between a surface of the first reflecting structure 102 on an opposite side to a side of the active layer 106 and the active layer 106 (specifically, between a surface of the first reflecting structure 102 on the side of the active layer 106 and the active layer 106), a metasurface 103 for generating an effective refractive index distribution in an in-plane direction that traps light.

The metasurface 103 is a two-dimensional arrangement of meta-atoms (unit structures) with a size similar to that of, for example, a sub-wavelength and enables an effective refractive index distribution in the in-plane direction with a light-trapping function to be flexibly designed. In other words, according to the surface-emitting laser 10, a surface-emitting laser with a high degree of freedom in setting an effective refractive index distribution in an in-plane direction of a light-trapping structure can be provided.

In particular, the surface-emitting laser 10 enables an effective refractive index distribution to be designed so as to resemble a graded index, which was not possible with conventional technologies, and enables more flexible design of light distribution and emission angle.

In addition, the surface-emitting laser 10 also enables polarization control by giving the meta-atoms (unit structures) anisotropy.

In addition, since the surface-emitting laser 10 can be mesa-less (mesa formation is not essential), the surface-emitting laser 10 offers a high degree of freedom in design, facilitates arraying, and also enables current constriction by ion implantation.

In addition, the surface-emitting laser 10 enables a phase shift amount of incident light to be controlled by the metasurface 103. In particular, a resonance wavelength (oscillation wavelength) can be controlled by arranging the metasurface 103 inside the resonator R.

In addition, the surface-emitting laser 10 can maintain a single-mode nature even when, for example, resonators are formed in an array pattern on a large-diameter wafer (to constitute a surface-emitting laser array).

In addition, the surface-emitting laser 10 enables a gradual mode distribution to be designed. Accordingly, a carrier spread can be matched to a mode spread and the number of modes present can be suppressed.

In addition, the surface-emitting laser 10 enables a coupled array to be formed. In other words, a non-light-emitting area between adjacent resonators R when arranging the resonators R in an array pattern can be minimized.

### 2. SURFACE-EMITTING LASER ACCORDING TO SECOND EMBODIMENT OF PRESENT TECHNIQUE

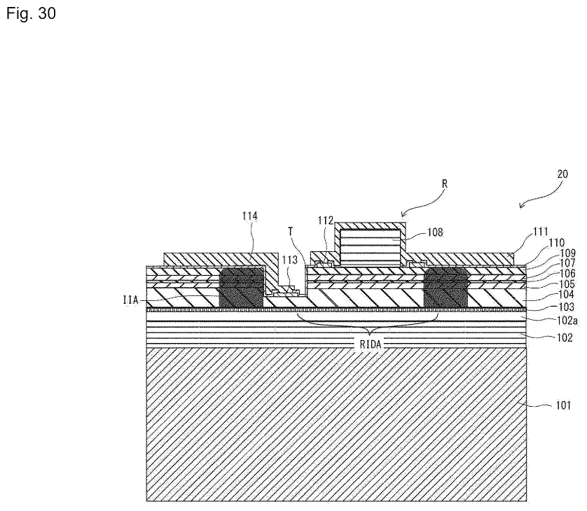

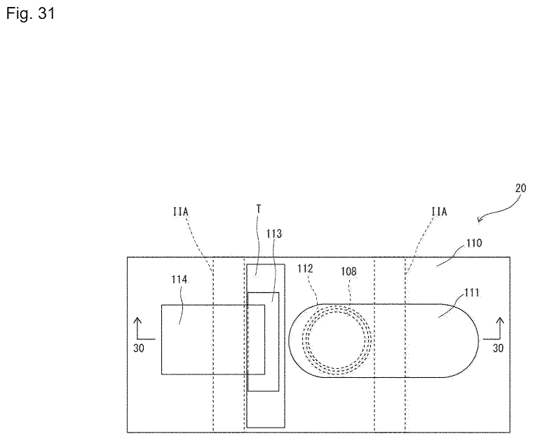

FIG. 30 is a sectional view of a surface-emitting laser 20 according to a second embodiment of the present technique. FIG. 31 is a plan view of the surface-emitting laser 20. FIG. 30 is a sectional view taken along line 30-30 in FIG. 31.

### <<Configuration of Surface-Emitting Laser>>

The surface-emitting laser 20 according to the second embodiment has a configuration similar to that of the surface-emitting laser 10 according to the first embodiment with the exception of a dielectric multilayer reflector being used as the first reflecting structure 102 and a hybrid mirror constituted of a dielectric multilayer reflector and a metal reflector stacked on top of each other being used as the second reflecting structure 108 and that the surface-emitting laser 20 is a bottom-emitting surface-emitting laser. In this case, the second pad metal 111 doubles as the metal reflector and a part of the anode electrode.

In the surface-emitting laser 20, the dielectric multilayer reflector as the first reflecting structure 102 has a structure in which a plurality of types (for example, two types) of dielectric layers with different refractive indices are alternately stacked with an optical thickness of ¼ wavelength of the oscillation wavelength. The first reflecting structure 102 is constituted of, for example, SiN/SiO₂. A reflectance of the first reflecting structure 102 is set slightly lower than a reflectance of the second reflecting structure 108. A SiN layer (high-refractive index layer) that is the uppermost layer 102a of the dielectric multilayer reflector as the first reflecting structure 102 is formed thicker than other refractive index layers. As an example, the first reflecting structure 102 has a reflectance of 90% or higher (preferably 93% or higher, more preferably 96% or higher, and even more preferably 99% or higher) relative to the oscillation wavelength of the surface-emitting laser 10. Note that the first reflecting structure 102 may be a hybrid mirror constituted of the dielectric multilayer reflector and a semiconductor multilayer reflector (for example, i-GaAs/AlGaAs).

The metasurface 103 is arranged between the uppermost layer 102a of the first reflecting structure 102 and the first contact layer 104. As an example, one of the first and second areas A1 and A2 of the metasurface 103 can be SiN and the other can be air.

The dielectric multilayer reflector of the second reflecting structure 108 is a small reflector provided on an inner diameter side of the second contact metal 112 on an upper surface of the second contact layer 109. The dielectric multilayer reflector is covered by the second pad metal 111. In other words, a hybrid mirror is constituted of the dielectric multilayer reflector and the second pad metal 111. The dielectric multilayer reflector is constituted of, for example. SiO₂/a-Si. As an example, the second reflecting structure 108 has a reflectance of 90% or higher (preferably 93% or higher, more preferably 96% or higher, and even more preferably 99% or higher) relative to the oscillation wavelength of the surface-emitting laser 10. Note that the second reflecting structure 108 may be a hybrid mirror constituted of the dielectric multilayer reflector and a semiconductor multilayer reflector (for example, p-GaAs/AlGaAs).

In the surface-emitting laser 20, two ion implantation areas IIA are provided so as to sandwich the first and second contact metals 113 and 112 in a plan view (refer to FIG. 31) and to straddle the first contact layer 104, the first cladding layer 105, the active layer 106, and the second cladding layer 107 in a side view (refer to FIG. 30). The trench T and the first contact metal 113 are provided, as an example, in a rectangular shape in a plan view.

The surface-emitting laser 20 can be mounted, for example, to the laser driver by junction-down (flip chip). Furthermore, each of the first and second pad metals 114 and 111 and a laser driver can be electrically connected via a bump.

### <<Operation of Surface-Emitting Laser>>

The surface-emitting laser 20 performs a similar operation to that of the surface-emitting laser 10 according to the first embodiment with the exception of emitting light to a rear surface side of the substrate 101.

### <<Manufacturing Method of Surface-Emitting Laser>>

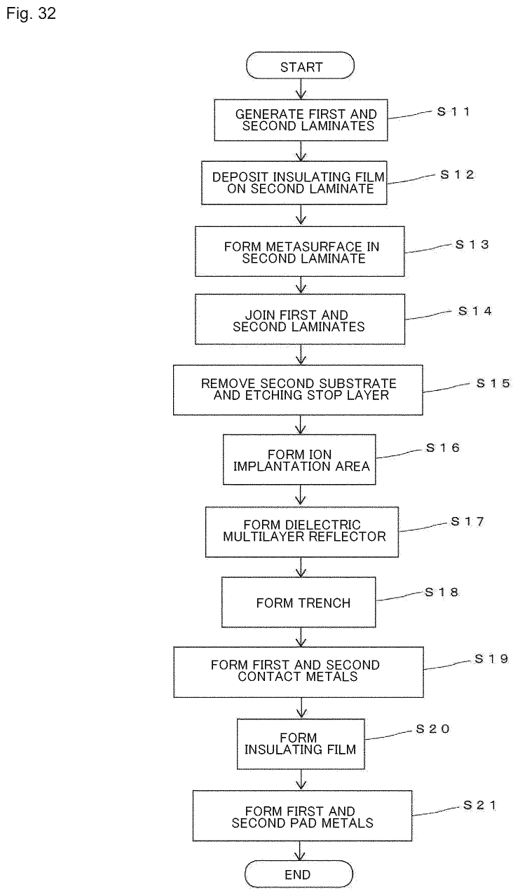

Hereinafter, a manufacturing method of the surface-emitting laser 20 will be described with reference to the flow chart shown in FIG. 32 and the like. Here, as an example, a plurality of surface-emitting lasers 20 are simultaneously generated on a single wafer (hereinafter referred to as a “substrate 101” for the sake of convenience) that is a base material of the substrate 101 by a semiconductor manufacturing method using semiconductor manufacturing equipment. Next, the plurality of surface-emitting lasers 20 that are integrated are separated from one another to obtain a plurality of chip-like surface-emitting lasers 20.

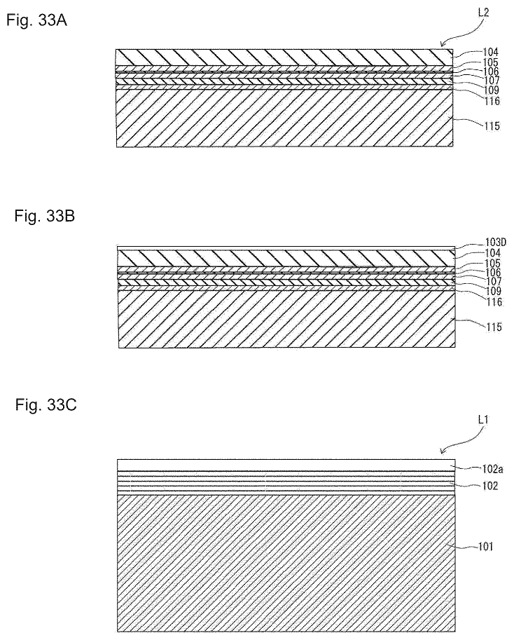

In a first step S11, first and second laminates L1 and L2 are generated. The first reflecting structure 102 (for example, SiN/SiO₂·DBR) is stacked (for example, epitaxially grown at a growth temperature of 605° C.) on the substrate 101 (a growth substrate as a first substrate) by, for example, a metal organic chemical vapor deposition (MOCVD) method to generate the first laminate L1 (refer to FIG. 33C). At this point, a SiN layer that is the uppermost layer 102a of the first reflecting structure 102 is formed thick. The etching stop layer 116 (for example, an InGaP layer), the second contact layer 109, the second cladding layer 107, the active layer 106 (for example, 5 stacks of 2QW), the first cladding layer 105, and the first contact layer 104 are stacked (for example, epitaxially grown at a growth temperature of 605° C.) in this order on the growth substrate 115 (for example, a GaAs substrate) as a second substrate by, for example, a metal organic chemical vapor deposition (MOCVD) method to generate the second laminate L2 (refer to FIG. 33A). Note that when performing MOCVD, for example, trimethylgallium ((CH₃)₃Ga) is used as a source gas for gallium, trimethylaluminum ((CH)₃Al) is used as a source gas for aluminum, trimethylindium ((CH₃)₃In) is used as a source gas for indium, and trimethylarsenic ((CH₃)₃As) is used as a source gas for As, respectively. In addition, for example, monosilane (SiH₄) is used as a source gas for silicon and carbon tetrabromide (CBr₄) is used as a source gas for carbon.

In a next step S12, an insulating film 103D is deposited on the second laminate (refer to FIG. 33B). Specifically, a SiN film as the insulating film 103D is formed over an entire surface of the second laminate on a side of the first contact layer 104 by vacuum evaporation, sputtering, or the like.

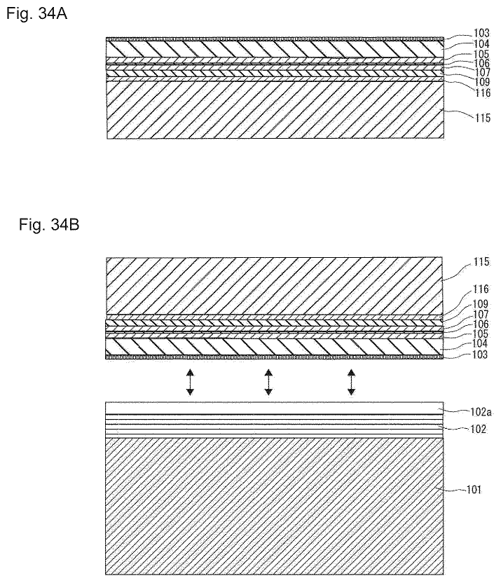

In a next step S13, the metasurface 103 is formed in the second laminate (refer to FIG. 34A). Specifically, for example, using electron beam lithography and dry etching (for example, ICP-RIE), an effective refractive index distribution area RIDA containing a plurality of unit structures 103a is formed on the insulating layer 103D formed on the surface of the second laminate on the side of the first contact layer 104. In this case, the metasurface 103 is formed so that one of the first and second areas A1 and A2 is SiN and the other is air. Note that the effective refractive index distribution area RIDA may be formed over the entire area of the metasurface 103 or only in a portion (for example, a central part).

In a next step S14, the first and second laminates are joined. Specifically, a surface of the first laminate on the side of the first reflecting structure 102 and a surface of the second laminate on the side of the metasurface 103 are joined, for example, by surface-activated bonding (refer to FIG. 34B).

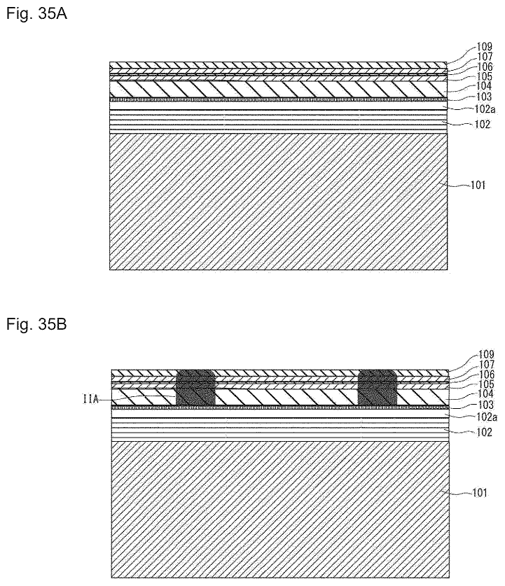

In a next step S15, the growth substrate 115 as the second substrate and the etching stop layer 116 are removed (refer to FIG. 35). Specifically, first, the growth substrate 115 as the second substrate is removed by wet etching. At this point, etching can be stopped by the etching stop layer 116. Next, the etching stop layer 116 is removed to expose the second contact layer 109.

In a next step S16, the ion implantation area IIA is formed (refer to FIG. 35B). Specifically photolithography is used to form a resist pattern covering an area of the second laminate other than an area where the ion implantation area IIA is to be formed and the resist pattern is used as a mask to perform ion implantation into the second laminate from the side of the second contact layer 109. An implantation depth of the ions at this point is at least until the ions reach inside the first cladding layer 105.

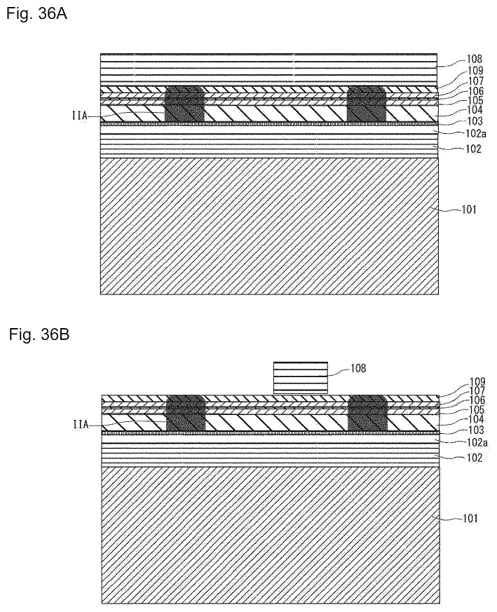

In a next step S17, the dielectric multilayer reflector of the second reflecting structure 108 is formed. Specifically, first, the dielectric multilayer reflector is deposited on a surface of the second laminate on the side of the second contact layer 109 (refer to FIG. 36A). Next, photolithography and etching are performed so that only the dielectric multilayer reflector of the second reflecting structure 108 remains (refer to FIG. 36B).

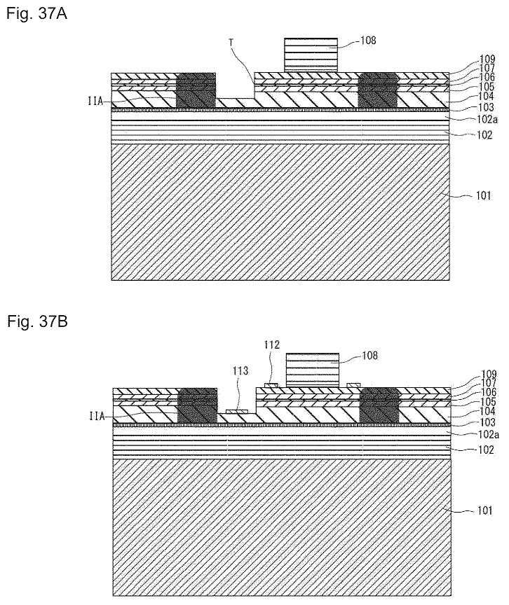

In a next step S18, the trench T is formed (refer to FIG. 37A). Specifically, photolithography is used to form a resist pattern having an opening at a location where the trench T of the second laminate is to be formed and the resist pattern is used as a mask to etch the second laminate from the side of the second contact layer 109 by dry etching. The etching at this point is to be performed until an etch bottom reaches inside the first contact layer 104. Subsequently, the resist pattern is removed.

In a next step S19, the first and second contact metals 113 and 112 are formed (refer to FIG. 37B). Specifically, for example, the first contact metal 113 is formed on a bottom surface of the trench T and the second contact metal 112 is formed in a ring shape on the second contact layer 109 so as to enclose the second reflecting structure 108 using, for example, a lift-off method.

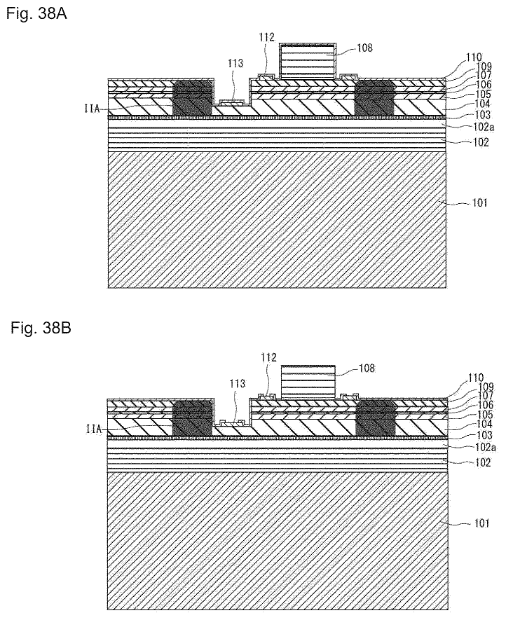

In a next step S20, the insulating film 110 is formed. Specifically, first, the insulating film 110 is formed over the entire surface by, for example, vapor deposition or sputtering (refer to FIG. 38A). Next, the insulating film 110 that covers the first contact metal 113, the insulating film 110 that covers the second contact metal 112, and an insulating film that covers the second reflecting structure 108 are removed by photolithography and etching (refer to FIG. 38B).

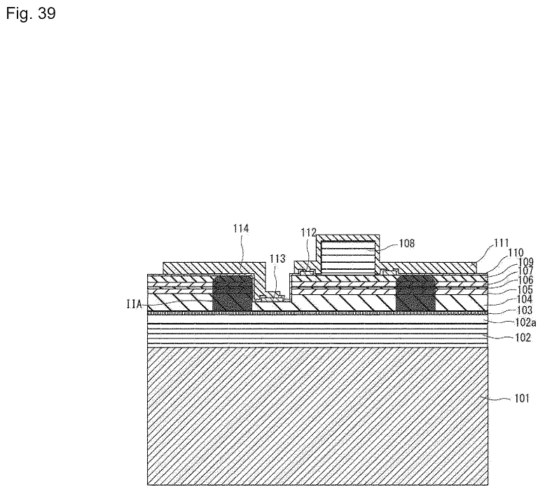

In a final step S21, the first and second pad metals 114 and 111 are formed (refer to FIG. 39). Specifically, for example, using a lift-off method, the first pad metal 114 is formed so that one side portion comes into contact with the first contact metal 113 in the trench T and another side portion is located around an opening of the trench T. For example, using a lift-off method, the second pad metal 111 is formed so as to straddle the insulating film 110 formed on the second contact layer 109, the second contact metal 112, and the second reflecting structure 108.

### <<Advantageous Effect of Surface-Emitting Laser>>

According to the surface-emitting laser 20, advantageous effects similar to those of the surface-emitting laser 10 according to the first embodiment can be produced.

### 3. SURFACE-EMITTING LASER ACCORDING TO THIRD EMBODIMENT OF PRESENT TECHNIQUE

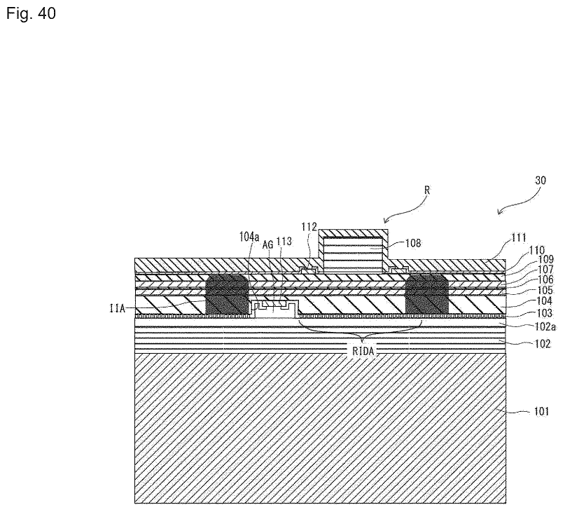

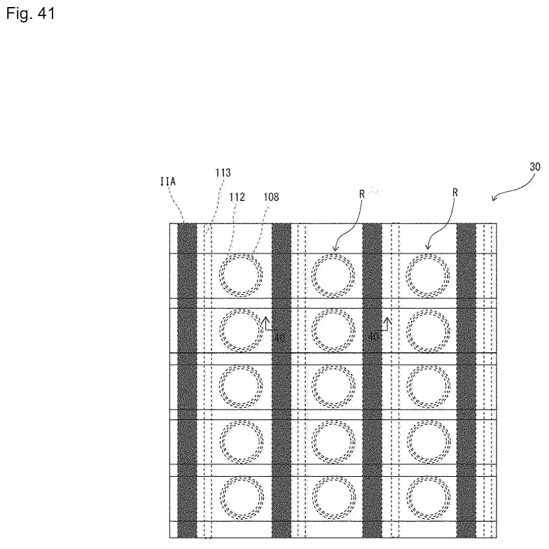

FIG. 40 is a sectional view of a surface-emitting laser 30 according to a third embodiment of the present technique. FIG. 41 is a plan view of the surface-emitting laser 30. FIG. 40 is a sectional view taken along line 40-40 in FIG. 41.

### <<Configuration of Surface-Emitting Laser>>

The surface-emitting laser 30 according to the third embodiment has a configuration more or less similar to that the surface-emitting laser 20 according to the second embodiment with the exception of the first contact metal 113 being arranged in an air gap AG defined by the first contact layer 104 and the first reflecting structure 102 as shown in FIG. 40 and the surface-emitting laser 30 constituting a surface-emitting laser array as shown in FIG. 41.

In the surface-emitting laser 30, as shown in FIG. 40, the air gap AG is formed due to an opening of a groove 104a formed on a surface (lower surface) of the first contact layer 104 on the side of the first reflecting structure 102 being covered by the first reflecting structure 102 from below. The first contact metal 113 is provided, as an example, on a bottom surface of the groove 104a formed in the first contact layer 104. In the surface-emitting laser 30, a cathode electrode is constituted of the first contact metal 113.

As shown in FIG. 41, the surface-emitting laser 30 constitutes a surface-emitting laser array in which a plurality of resonators R are arranged in an array pattern (for example, a matrix pattern).

As an example, the air gap AG corresponding to each column of the array and the first contact metal 113 arranged in the air gap AG extend over an entire row direction of the array and are provided in common to the plurality of resonators R arranged in the row direction. One end and/or another end of the first contact metal 113 is connected to a cathode side of a laser driver.

### <<Operation of Surface-Emitting Laser>>

The surface-emitting laser 30 performs a similar operation to that of the surface-emitting laser 20 according to the second embodiment.

### <<Manufacturing Method of Surface-Emitting Laser>>

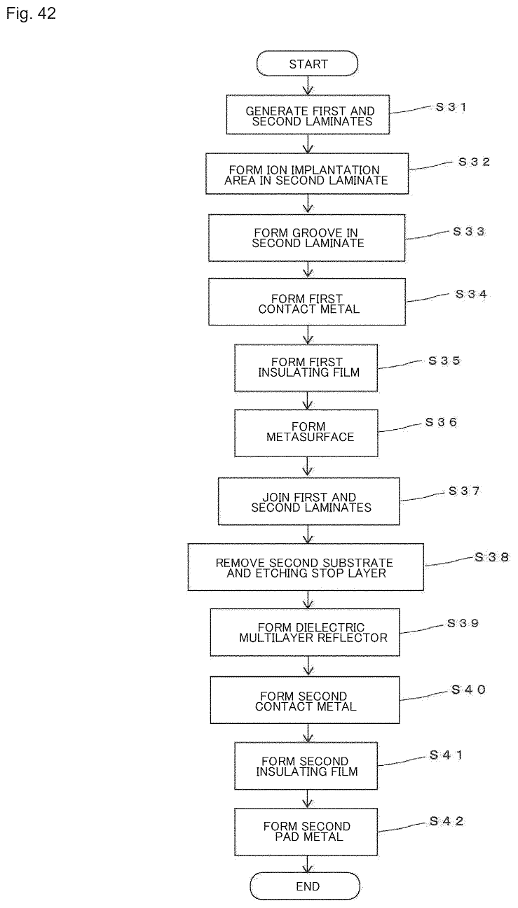

Hereinafter, a manufacturing method of the surface-emitting laser 30 will be described with reference to the flow chart shown in FIG. 42 and the like. Here, as an example, a plurality of surface-emitting lasers 30 are simultaneously generated on a single wafer (hereinafter referred to as a “substrate 101” for the sake of convenience) that is a base material of the substrate 101 by a semiconductor manufacturing method using semiconductor manufacturing equipment. Next, the plurality of surface-emitting lasers 30 that are integrated are separated from one another to obtain a plurality of chip-like surface-emitting lasers 30.

In a first step S31, first and second laminates L1 and L2 are generated. The first reflecting structure 102 (for example, SiN/SiO₂·DBR) is stacked (for example, epitaxially grown at a growth temperature of 605° C.) on the substrate 101 (a growth substrate as a first substrate) by, for example, a metal organic chemical vapor deposition (MOCVD) method to generate the first laminate L1 (refer to FIG. 33C). At this point, a SiN layer that is the uppermost layer 102a of the first reflecting structure 102 is formed thick. The etching stop layer 116 (for example, an InGaP layer), the second contact layer 109, the second cladding layer 107, the active layer 106 (for example, 9 stacks of 3QW), the first cladding layer 105, and the first contact layer 104 are stacked (for example, epitaxially grown at a growth temperature of 605° C.) in this order on the growth substrate 115 (for example, a GaAs substrate) as a second substrate by, for example, a metal organic chemical vapor deposition (MOCVD) method to generate the second laminate L2 (refer to FIG. 33A). Note that when performing MOCVD, for example, trimethylgallium ((CH₃)₃Ga) is used as a source gas for gallium, trimethylaluminum ((CH₃)₃Al) is used as a source gas for aluminum, trimethylindium ((CH₃)₃In) is used as a source gas for indium, and trimethylarsenic ((CH₃)₃As) is used as a source gas for As, respectively. In addition, for example, monosilane (SiH₄) is used as a source gas for silicon and carbon tetrabromide (CBr₄) is used as a source gas for carbon.

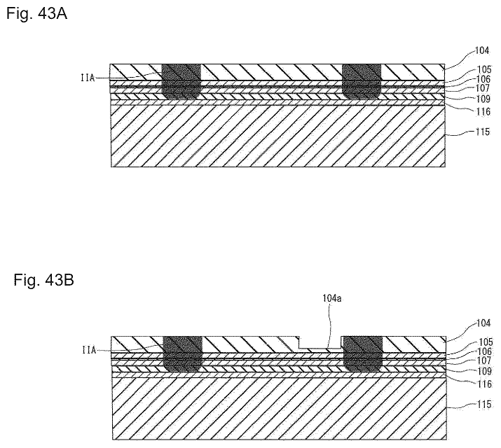

In a next step S32, the ion implantation area IIA is formed in the second laminate (refer to FIG. 43A). Specifically photolithography is used to form a resist pattern covering an area of the second laminate other than an area where the ion implantation area IIA is to be formed and the resist pattern is used as a mask to perform ion implantation into the second laminate from the side of the first contact layer 104. An implantation depth of the ions at this point is at least until the ions reach inside the second contact layer 109.

In a next step S33, the groove 104a is formed in the second laminate (refer to FIG. 43B). Specifically, photolithography is used to form a resist pattern having an opening at a location where the groove 104a of the second laminate is to be formed and the resist pattern is used as a mask to etch the second laminate by dry etching. The etching at this point is to be performed so that an etch bottom remains inside the first contact layer 104. Subsequently, the resist pattern is removed.

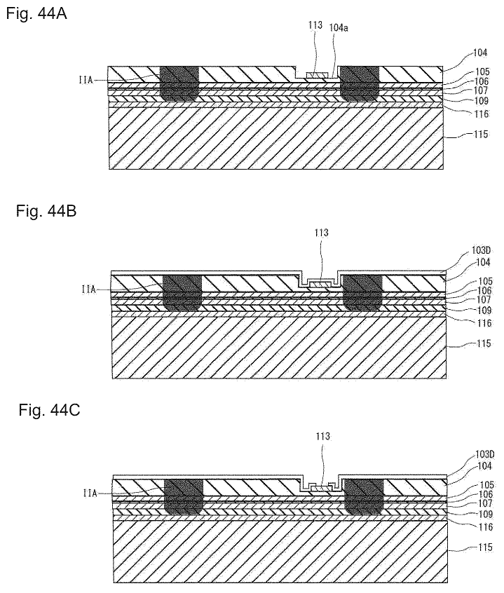

In a next step S34, the first contact metal 113 is formed (refer to FIG. 44A). Specifically for example, the first contact metal 113 is formed in an elongated manner on a bottom surface of the elongated groove 104a using, for example, a lift-off method.

In a next step S35, the insulating film 103D is formed. Specifically, first, a SiN film as the insulating film 103D is formed over an entire surface of the second laminate on a side of the first contact layer 104 by vacuum evaporation, sputtering, or the like (refer to FIG. 44B). Next, the insulating film 103D that covers the first contact metal 113 is removed by photolithography and etching (refer to FIG. 44C).

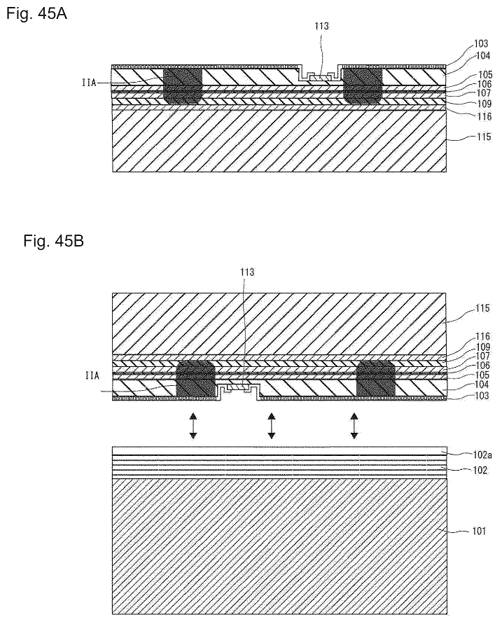

In a next step S36, the metasurface 103 is formed in the second laminate (refer to FIG. 45A). Specifically, for example, using electron beam lithography and dry etching (for example, ICP-RIE), an effective refractive index distribution area RIDA containing a plurality of unit structures 103a is formed on the insulating layer 103D formed on the surface of the second laminate on the side of the first contact layer 104. In this case, the metasurface 103 is formed so that one of the first and second areas A1 and A2 is SiN and the other is air. Note that the effective refractive index distribution area RIDA may be formed over the entire area of the metasurface 103 or only in a portion (for example, a central part).

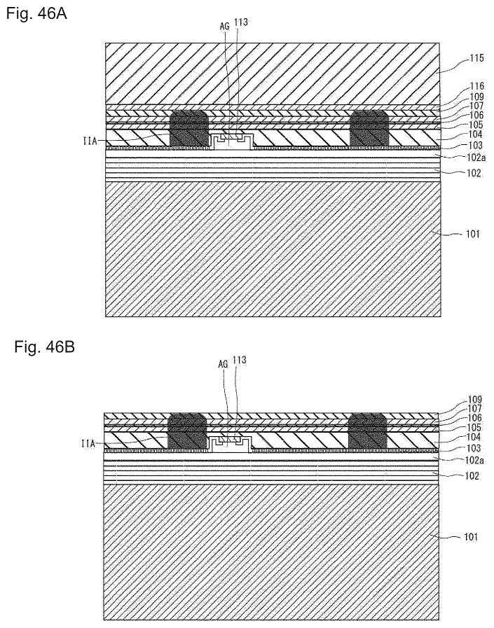

In a next step S37, the first and second laminates are joined. Specifically, a surface of the first laminate on the side of the first reflecting structure 102 and a surface of the second laminate on the side of the metasurface 103 are joined, for example, by surface-activated bonding (refer to FIGS. 45B and 46A).

In a next step S38, the growth substrate 115 as the second substrate and the etching stop layer 116 are removed (refer to FIG. 46B). Specifically, first, the growth substrate 115 as the second substrate is removed by wet etching. At this point, etching can be stopped by the etching stop layer 116. Next, the etching stop layer 116 is removed to expose the second contact layer 109.

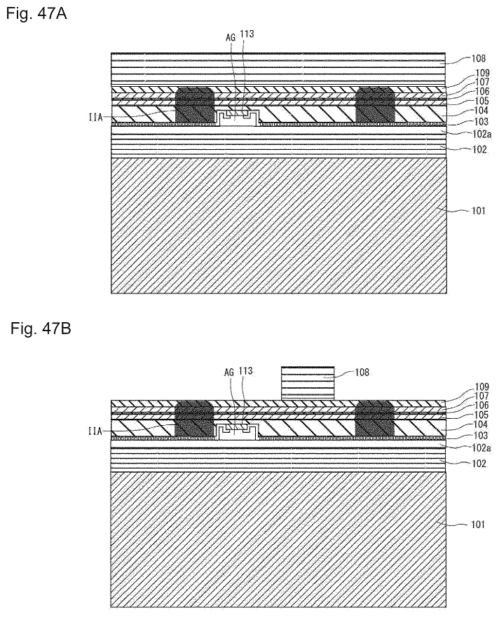

In a next step S39, the dielectric multilayer reflector of the second reflecting structure 108 is formed. Specifically, first, the dielectric multilayer reflector is deposited on a surface of the second laminate on the side of the second contact layer 109 (refer to FIG. 47A). Next, photolithography and etching are performed so that only the dielectric multilayer reflector of the second reflecting structure 108 remains (refer to FIG. 47B).

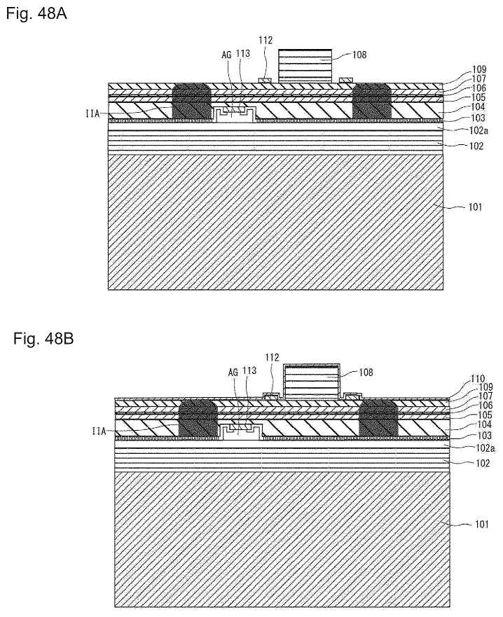

In a next step S40, the second contact metal 112 is formed (refer to FIG. 48A). Specifically, for example, the second contact metal 112 is formed in a ring shape on the second contact layer 109 so as to enclose the second reflecting structure 108 using, for example, a lift-off method.

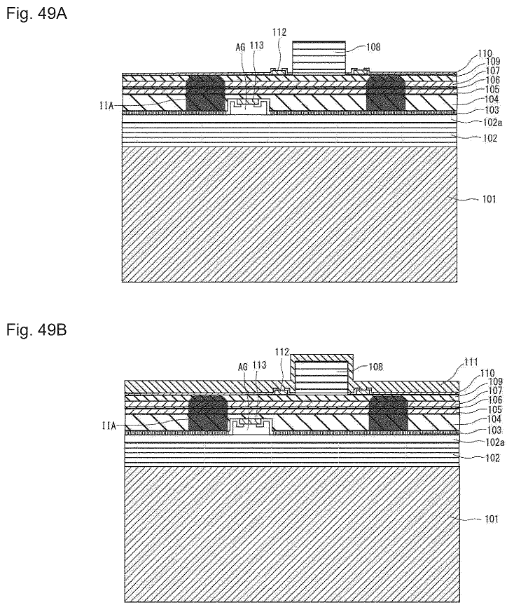

In a next step S41, the second insulating film 110 is formed. Specifically, first, the insulating film 110 is formed over the entire surface by, for example, vapor deposition or sputtering (refer to FIG. 48B). Next, the insulating film 110 that covers the second contact metal 112, and an insulating film that covers the second reflecting structure 108 are removed by photolithography and etching (refer to FIG. 49A).

In a final step S42, the second pad metal 111 is formed (refer to FIG. 49B). Specifically, the second pad metal 111 is formed so as to straddle the insulating film 110 formed on the second contact layer 109, the second contact metal 112, and the second reflecting structure 108 using, for example, a lift-off method.

### <<Advantageous Effect of Surface-Emitting Laser>>

According to the surface-emitting laser 30, advantageous effects similar to those of the surface-emitting laser 10 according to the first embodiment can be produced.

### 4. SURFACE-EMITTING LASER ACCORDING TO FOURTH EMBODIMENT OF PRESENT TECHNIQUE

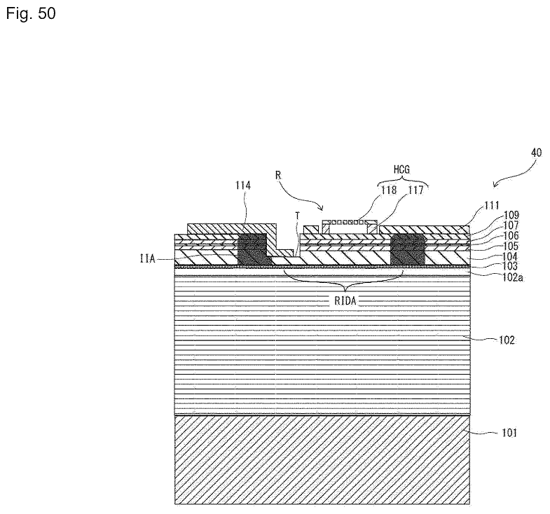

FIG. 50 is a sectional view of a surface-emitting laser 40 according to a fourth embodiment of the present technique.

### <<Configuration of Surface-Emitting Laser>>

The surface-emitting laser 40 has a configuration more or less similar to that the surface-emitting laser 10 according to the first embodiment with the exception of an HCG (high-contrast grating) being used as the second reflecting structure. HCG, also referred to as a high-refractive index difference subwavelength diffraction grating, is capable of achieving high reflectivity with a thin layer thickness and also has a polarization control function.

The HCG as the second reflecting structure includes a sacrificial layer 117 and an HCG layer 118 provided on the sacrificial layer 117. The HCG layer 118 is constituted of, for example, i-GaAs. The sacrificial layer 117 is constituted of, for example, i-AlGaAs.

As an example, the HCG as the second reflecting structure has a reflectance of 90% or higher (preferably 93% or higher, more preferably 96% or higher, and even more preferably 99% or higher) relative to the oscillation wavelength of the surface-emitting laser 10.

In the surface-emitting laser 40, a cathode electrode is solely constituted of the first pad metal 114 and an anode electrode is solely constituted of the second pad metal 111.

### <<Operation of Surface-Emitting Laser>>

The surface-emitting laser 40 performs a similar operation to that of the surface-emitting laser 10 according to the first embodiment.

### <<Manufacturing Method of Surface-Emitting Laser>>

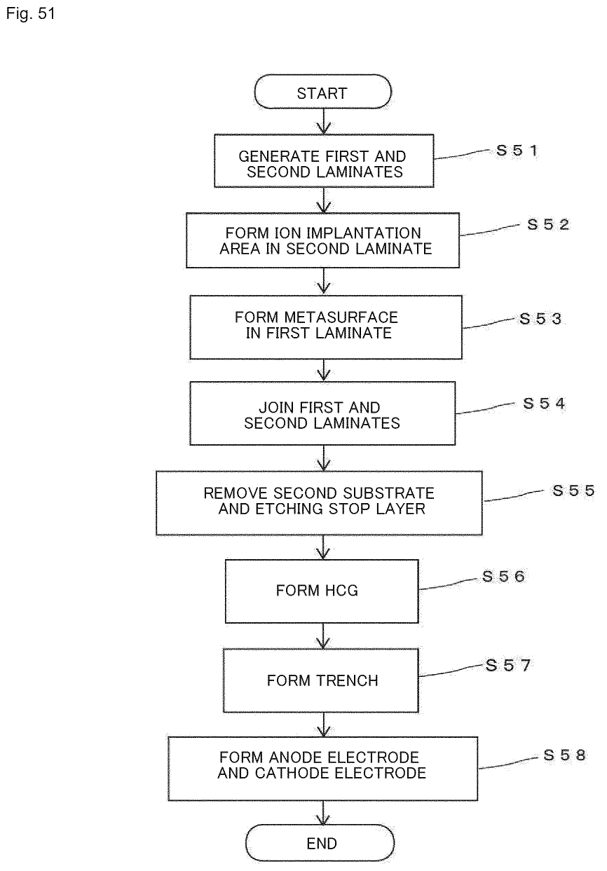

Hereinafter, a manufacturing method of the surface-emitting laser 40 will be described with reference to the flow chart shown in FIG. 51 and the like. Here, as an example, a plurality of surface-emitting lasers 40 are simultaneously generated on a single wafer (hereinafter referred to as a “substrate 101” for the sake of convenience) that is a base material of the substrate 101 by a semiconductor manufacturing method using semiconductor manufacturing equipment. Next, the plurality of surface-emitting lasers 40 that are integrated are separated from one another to obtain a plurality of chip-like surface-emitting lasers 40.

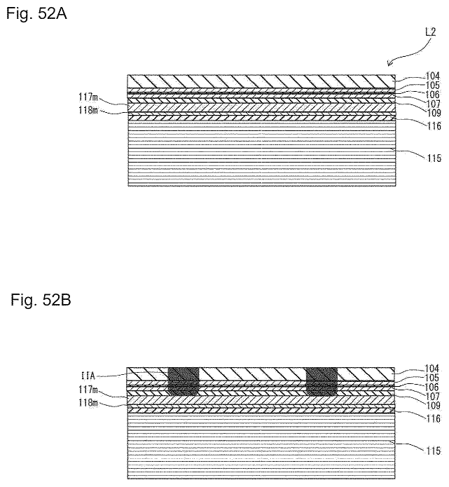

In a first step S51, first and second laminates L1 and L2 are generated. The first reflecting structure 102 (for example, i-GaAs/AlGaAs·DBR) is stacked (for example, epitaxially grown at a growth temperature of 605° C.) on the substrate 101 (a growth substrate as a first substrate) by, for example, a metal organic chemical vapor deposition (MOCVD) method to generate the first laminate L1 (refer to FIG. 20B). At this point, an i-GaAs layer that is the uppermost layer 102a of the first reflecting structure 102 is formed thick. The etching stop layer 116 (for example, an InGaP layer), an i-GaAs layer 118m that is a material of the HCG layer 118, an i-AlGaAs layer 117m that is a material of the sacrificial layer 117, the second contact layer 109, the second cladding layer 107, the active layer 106 (for example, 3QW), the first cladding layer 105, and the first contact layer 104 are stacked (for example, epitaxially grown at a growth temperature of 605° C.) in this order on the growth substrate 115 (for example, a GaAs substrate) as a second substrate by, for example, a metal organic chemical vapor deposition (MOCVD) method to generate the second laminate L2 (refer to FIG. 52A). Note that when performing MOCVD, for example, trimethylgallium ((CH₃)₃Ga) is used as a source gas for gallium, trimethylaluminum ((CH)₃Al) is used as a source gas for aluminum, trimethylindium ((CH₃)₃In) is used as a source gas for indium, and trimethylarsenic ((CH₃)₃As) is used as a source gas for As, respectively. In addition, for example, monosilane (SiH₄) is used as a source gas for silicon and carbon tetrabromide (CBr₄) is used as a source gas for carbon.

In a next step S52, the ion implantation area IIA is formed in the second laminate (refer to FIG. 52B). Specifically, photolithography is used to form a resist pattern covering an area of the second laminate other than an area where the ion implantation area IIA is to be formed and the resist pattern is used as a mask to perform ion implantation into the second laminate from the side of the first contact layer 104. An implantation depth of the ions at this point is at least until the ions reach inside the second cladding layer 107.

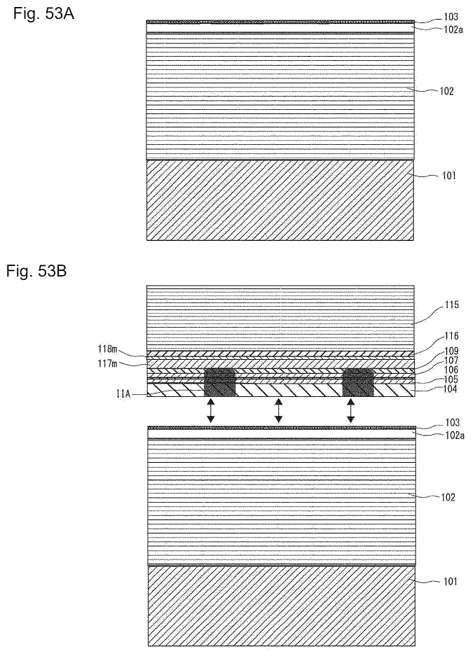

In a next step S53, the metasurface 103 is formed in the first laminate (refer to FIG. 53A). Specifically, for example, using electron beam lithography and dry etching (for example, ICP-RIE), an effective refractive index distribution area RIDA containing a plurality of unit structures 103a is formed on the surface of the uppermost layer 102a of the first reflecting structure 102. In this case, the metasurface 103 is formed so that one of the first and second areas A1 and A2 is i-GaAs and the other is air. Note that the effective refractive index distribution area RIDA may be formed over the entire area of the metasurface 103 or only in a portion (for example, a central part).

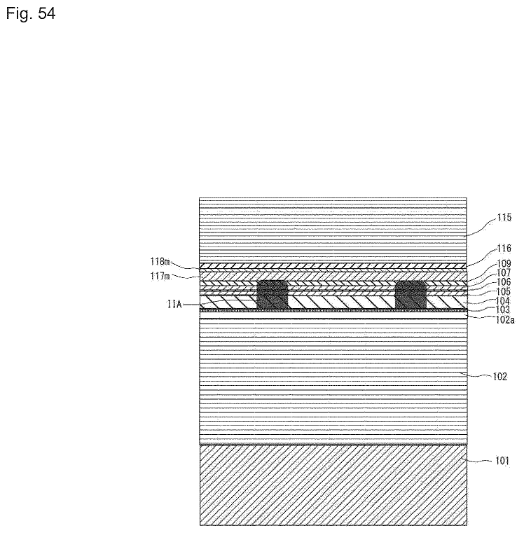

In a next step S54, the first and second laminates are joined. Specifically, a surface of the first laminate on the side of the metasurface 103 and a surface of the second laminate on the side of the first contact layer 104 are joined, for example, by surface-activated bonding (refer to FIGS. 53B and 54).

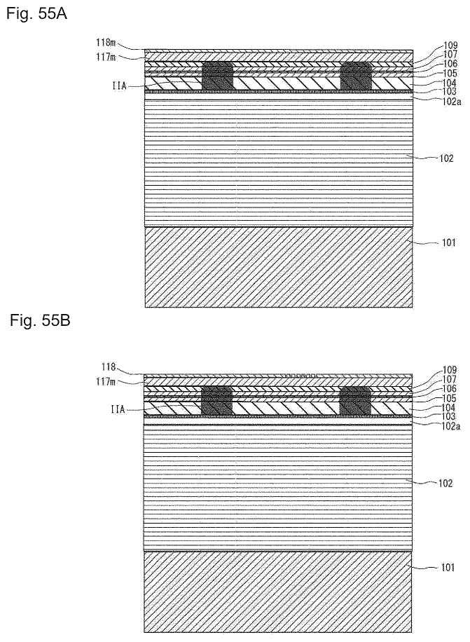

In a next step S55, the growth substrate 115 as the second substrate and the etching stop layer 116 are removed (refer to FIG. 55A). Specifically, first, the growth substrate 115 as the second substrate is removed by wet etching. At this point, etching can be stopped by the etching stop layer 116. Next, the etching stop layer 116 is removed to expose the i-GaAs layer 118m that is a material of the HCG layer 118.

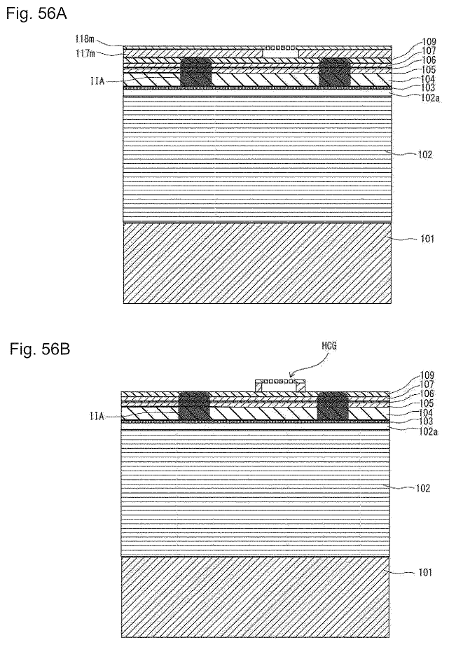

In a next step S56, the HCG is formed. Specifically, first, an HCG pattern (diffraction grating pattern) is formed on the i-GaAs layer 118m to form the HCG layer 118 using, for example, electron beam lithography and dry etching (for example, ICP-RIE) (refer to FIG. 55B). Next, an area of the i-AlGaAs layer 117m directly below the HCG pattern is selectively removed by sacrificial layer etching (refer to FIG. 56A). Next, an unwanted portion of the i-GaAs layer 118m and an unwanted portion of the i-AlGaAs layer 118m are removed by photolithography and etching (refer to FIG. 56B).

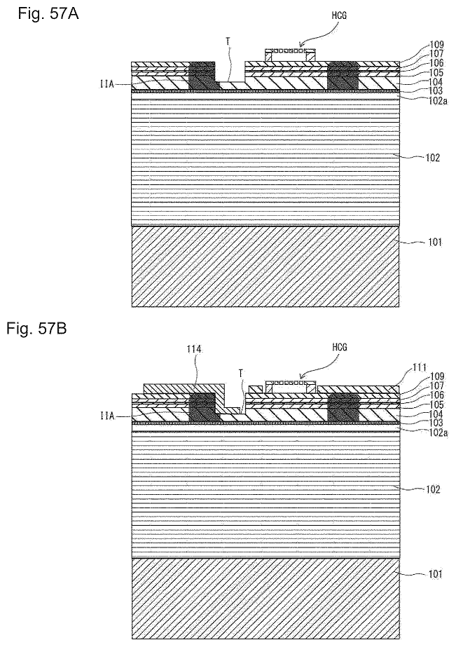

In a next step S57, the trench T is formed (refer to FIG. 57A). Specifically, photolithography is used to form a resist pattern having an opening at a location where the trench T of the second laminate is to be formed and the resist pattern is used as a mask to etch the second laminate from the side of the second contact layer 109 by dry etching. The etching at this point is to be performed until an etch bottom reaches inside the first contact layer 104. Subsequently, the resist pattern is removed.

In a final step S58, the second pad metal 111 as an anode electrode and the first pad metal 114 as a cathode electrode are formed (refer to FIG. 57B). Specifically, for example, using a lift-off method, the first pad metal 114 is formed in a crank-shaped cross section so that one side portion comes into contact with the first contact layer 104 in the trench T and another side portion is located around an opening of the trench T. For example, using a lift-off method, the second pad metal 111 is formed so that one side portion encloses the HCG and another side portion extends away from the cathode electrode.

### <<Advantageous Effect of Surface-Emitting Laser>>

According to the surface-emitting laser 40, advantageous effects similar to those of the surface-emitting laser 10 according to the first embodiment can be produced and, at the same time, the second reflecting structure, and thus the surface-emitting laser 40, can be made thinner.

### 5. MODIFICATIONS OF PRESENT TECHNIQUE

The present technique is not limited to the respective embodiments described above and various modifications can be made.

In surface-emitting lasers according to the present technique, the arrangement of the metasurface 103 can be modified as follows.

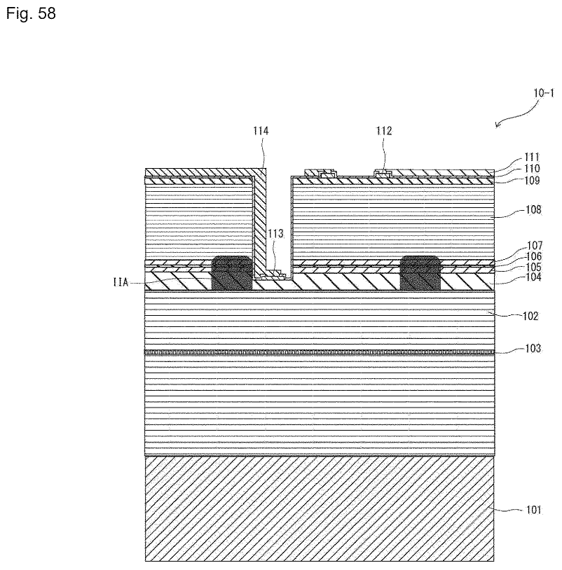

For example, the metasurface 103 may be provided within the first reflecting structure 102 as in a surface-emitting laser 10-1 according to a first modification of the first embodiment shown in FIG. 58.

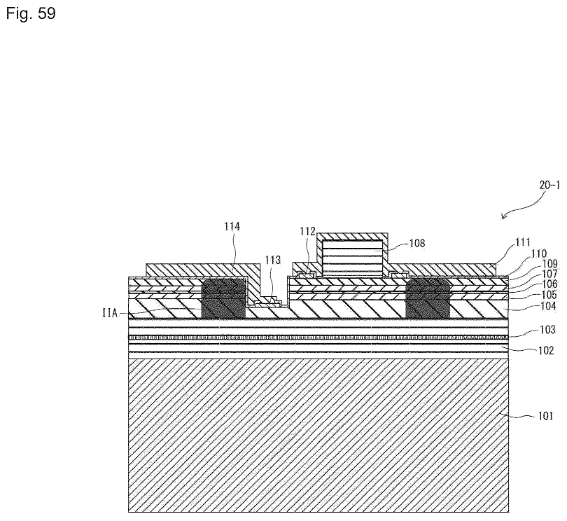

For example, the metasurface 103 may be provided within the first reflecting structure 102 as in a surface-emitting laser 20-1 according to a first modification of the second embodiment shown in FIG. 59.

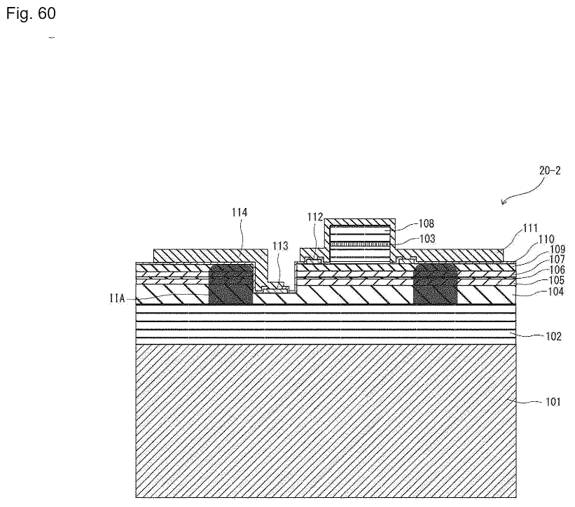

For example, the metasurface 103 may be provided within the second reflecting structure 108 as in a surface-emitting laser 20-2 according to a second modification of the second embodiment shown in FIG. 60.

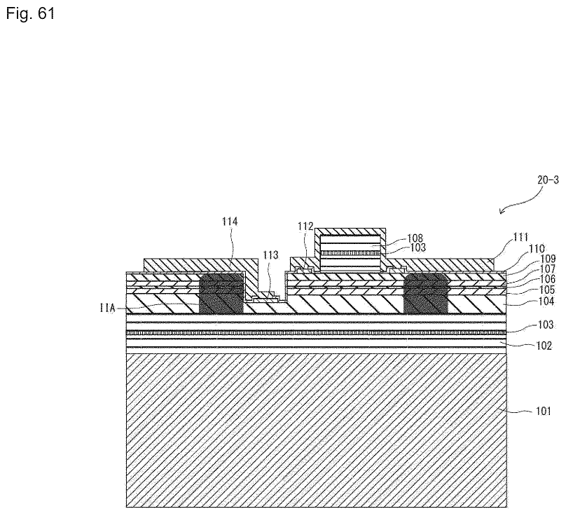

For example, the metasurface 103 may be provided within both the first and second reflecting structures 102 and 108 as in a surface-emitting laser 20-3 according to a third modification of the second embodiment shown in FIG. 61.

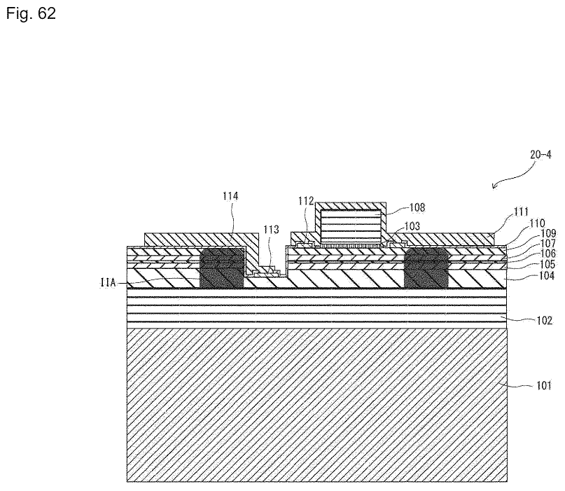

For example, the metasurface 103 may be provided between the second reflecting structure 108 and the active layer 106 (for example, between the second reflecting structure 108 and the second contact layer 109) as in a surface-emitting laser 20-4 according to a fourth modification of the second embodiment shown in FIG. 62.

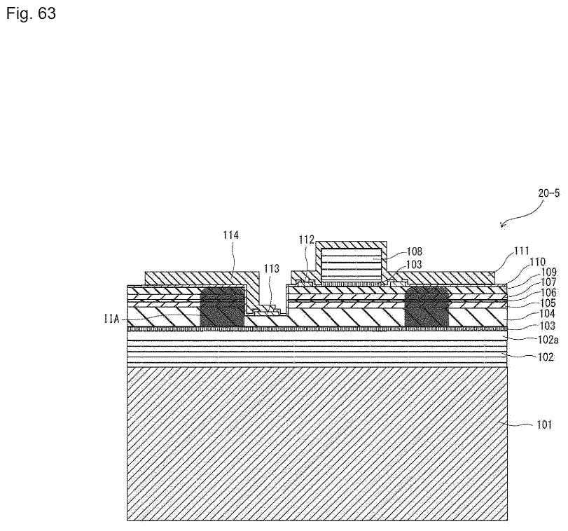

For example, the metasurface 103 may be provided between the second reflecting structure 108 and the active layer 106 (for example, between the second reflecting structure 108 and the second contact layer 109) and between the first reflecting structure 102 and the active layer 106 (for example, between the first reflecting structure 102 and the first contact layer 104) as in a surface-emitting laser 20-5 according to a fifth modification of the second embodiment shown in FIG. 63.

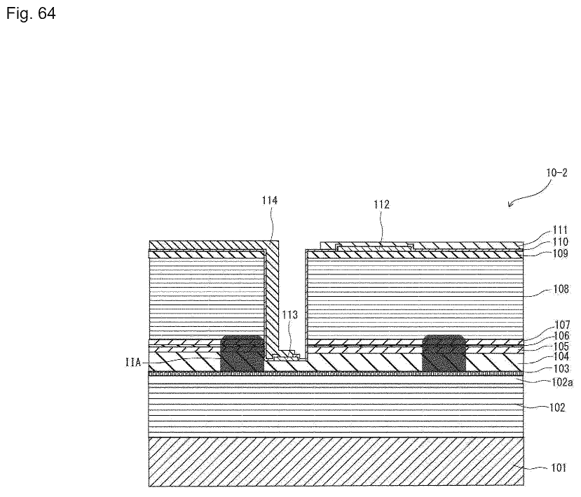

In addition, although the surface-emitting laser 10 according to the first embodiment is a top-emitting surface-emitting laser, for example, a bottom-emitting surface-emitting laser in which the second contact metal 112 is provided in a solid pattern as in a surface-emitting laser 10-2 according to a second modification of the first embodiment shown in FIG. 64 can also be configured.

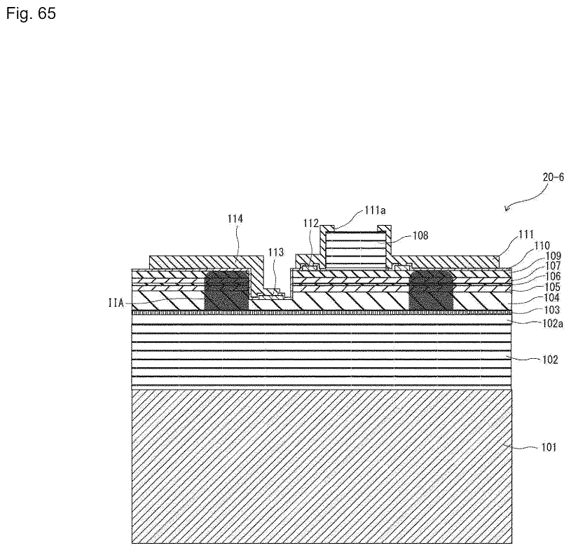

In addition, although the surface-emitting laser 20 according to the second embodiment is a bottom-emitting surface-emitting laser, for example, a top-emitting surface-emitting laser in which an opening (emission port) is provided in an area above the second reflecting structure 108 of the second pad metal 111 as in a surface-emitting laser 20-6 according to a sixth modification of the second embodiment shown in FIG. 65 can also be configured.

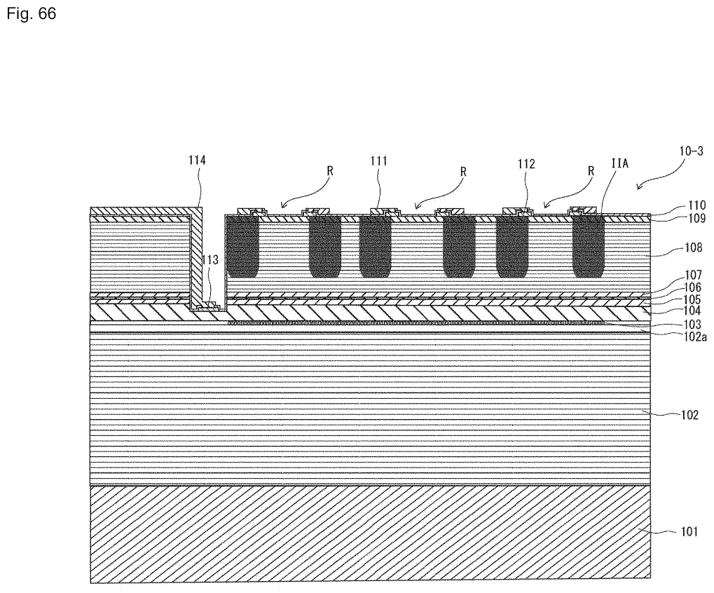

In addition, a surface-emitting laser array (cathode common) in which a plurality of resonators R are arranged in an array pattern as in a surface-emitting laser 10-3 according to a third modification of the first embodiment shown in FIG. 66 can also be configured. In this case, each resonator R can also be independently driven by making the anode electrodes provided in the respective resonators R independent (insulated) from each other.

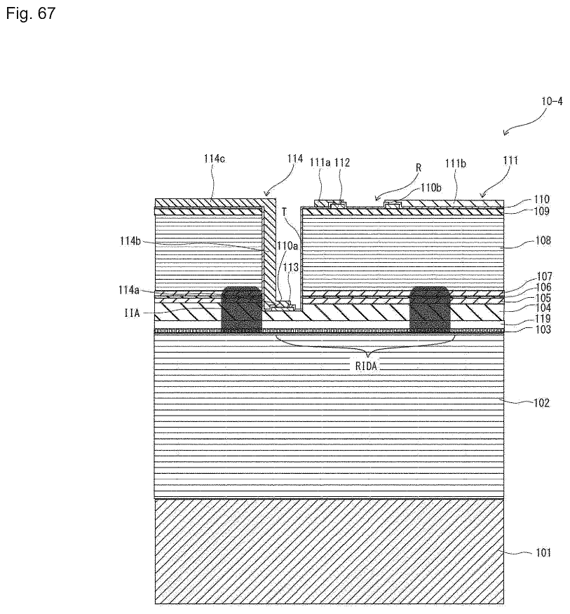

In addition, the metasurface 103 may be arranged between an intermediate layer 119 (for example, an i-GaAs layer) and the second reflecting structure 102 as in a surface-emitting laser 10-4 according to a fourth modification of the first embodiment shown in FIG. 67. In this case, the ion implantation area IIA is also provided in the intermediate layer 119 and the metasurface 103.

Hereinafter, a manufacturing method of the surface-emitting laser 10-4 will be briefly described.

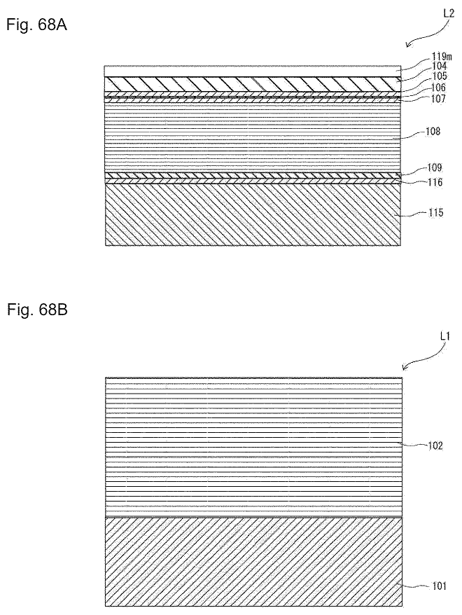

First, the first and second laminates L1 and L2 are generated. The first reflecting structure 102 (for example, i-GaAs/AlGaAs·DBR) is stacked on the substrate 101 (a growth substrate as a first substrate) by, for example, a metal organic chemical vapor deposition (MOCVD) method to generate the first laminate L1 (refer to FIG. 68B). The etching stop layer 116 (for example, an InGaP layer), the second contact layer 109, the second reflecting structure 108, the second cladding layer 107, the active layer 106 (for example, 3QW), the first cladding layer 105, the first contact layer 104, and an i-GaAs layer 119m that is a material of the intermediate layer 119 are stacked in this order on the growth substrate 115 (for example, a GaAs substrate) as a second substrate by, for example, a metal organic chemical vapor deposition (MOCVD) method to generate the second laminate L2 (refer to FIG. 68A).

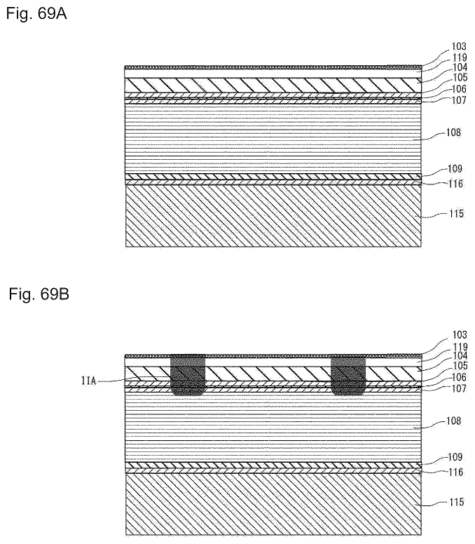

Next, the metasurface 103 is formed in the first laminate (refer to FIG. 69A). Specifically, for example, using electron beam lithography and dry etching (for example, ICP-RIE), an effective refractive index distribution area RIDA containing a plurality of unit structures 103a is formed on a surface of the i-GaAs layer 119m. In this case, the metasurface 103 is formed so that one of the first and second areas A1 and A2 is i-GaAs and the other is air. Note that the effective refractive index distribution area RIDA may be formed over the entire area of the metasurface 103 or only in a portion (for example, a central part).

Next, the ion implantation area IIA is formed in the second laminate (refer to FIG. 69B). Specifically, photolithography is used to form a resist pattern covering an area of the second laminate other than an area where the ion implantation area IIA is to be formed and the resist pattern is used as a mask to perform ion implantation into the second laminate from the side of the metasurface 103. An implantation depth of the ions at this point is at least until the ions reach inside the second cladding layer 107.

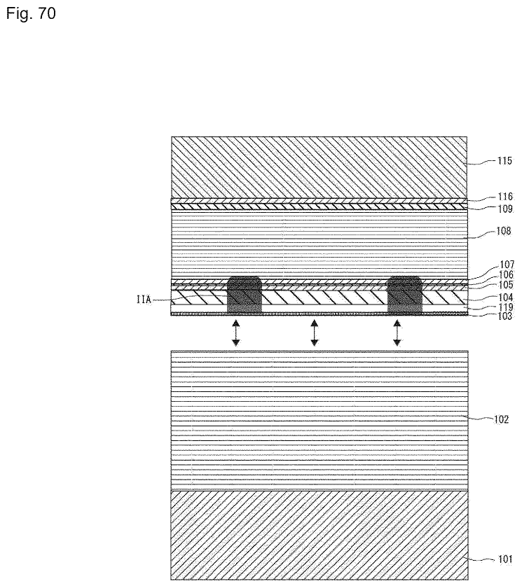

Next, the first and second laminates are joined. Specifically, a surface of the first laminate on the side of the first reflecting structure 102 and a surface of the second laminate on the side of the metasurface 103 are joined, for example, by surface-activated bonding (refer to FIG. 70). Subsequently, procedures similar to steps S5 to S9 in the flow chart shown in FIG. 19 are performed.

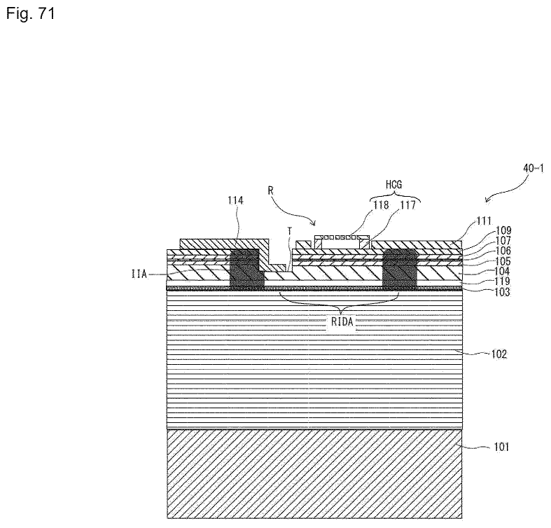

In addition, the metasurface 103 may be arranged between the intermediate layer 119 (for example, an i-GaAs layer) and the second reflecting structure 102 as in a surface-emitting laser 40-1 according to a first modification of the fourth embodiment shown in FIG. 71. In this case, the ion implantation area IIA is also provided in the intermediate layer 119 and the metasurface 103. The surface-emitting laser 40-1 can be manufactured by a manufacturing method that combines the manufacturing method of the surface-emitting laser 40 according to the fourth embodiment and the manufacturing method of the surface-emitting laser 10-4 shown in FIG. 67.

In addition, while the metasurface 103 is arranged at a position deviated from a current pathway from the anode electrode to the cathode electrode in the respective embodiments and the respective modifications described above, alternatively, the metasurface 103 may be arranged on the current pathway as described below.

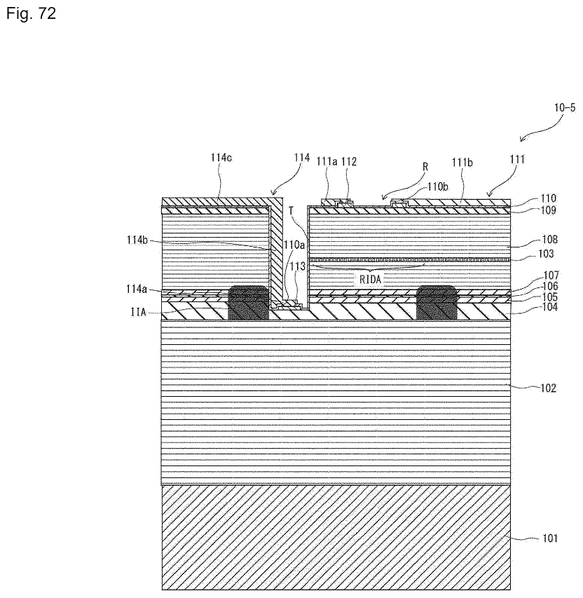

For example, the metasurface 103 is provided within the second reflecting structure 108 in a surface-emitting laser 10-5 according to a fifth modification of the first embodiment shown in FIG. 72. In this case, in the metasurface 103, at least one of the first and second areas A1 and A2 is constituted of a material with conductivity (for example, a conductor or a semiconductor with conductivity). In particular, configuring the metasurface 103 so that an electrical resistance of an area of the metasurface 103 corresponding to the light-emitting area of the active layer 106 is lower than that of the surrounding area enables the metasurface 103 to also have a current constriction function. In this case, a dedicated current constriction area like the ion implantation area IIA is no longer necessary.

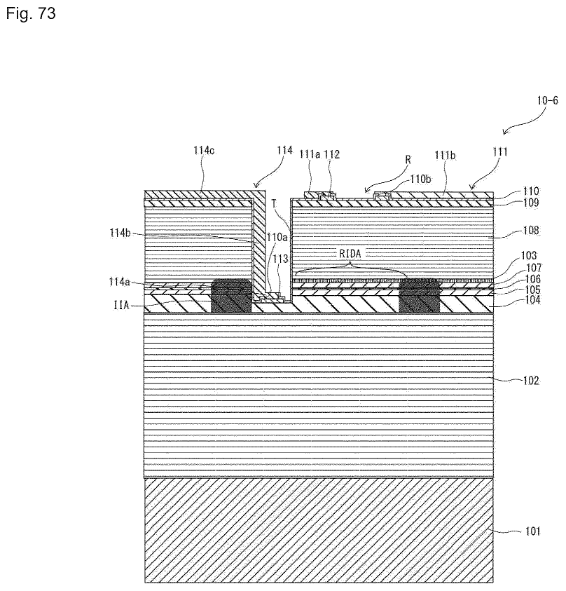

For example, in a surface-emitting laser 10-6 according to a sixth modification of the first embodiment shown in FIG. 73, the metasurface 103 is provided between the second reflecting structure 108 and the active layer 106 (for example, between the second reflecting structure 108 and the second cladding layer 107). In this case, in the metasurface 103, at least one of the first and second areas A1 and A2 is constituted of a material with conductivity (for example, a conductor or a semiconductor with conductivity). In particular, configuring the metasurface 103 so that an electrical resistance of an area of the metasurface 103 corresponding to the light-emitting area of the active layer 106 is lower than that of the surrounding area enables the metasurface 103 to also have a current constriction function. In this case, a dedicated current constriction area like the ion implantation area IIA is no longer necessary.

(Example of Fabrication Method of Metasurface in which First and Second Areas are Constituted of Dielectric Bodies)

For example, when fabricating the metasurface 103 constituted of SiN/a-Si, after patterning the plurality of unit structures 103a that constitute the first area A1 on a SiN film using, for example, electron beam lithography and dry etching, the periphery of each unit structure 103a may be embedded with a-Si and planarized by a damascene process.

(Another Example of Fabrication Method of Metasurface in which First and Second Areas are Constituted of Dielectric Bodies)

For example, when fabricating the metasurface 103 constituted of SiN/polyimide, after patterning the plurality of unit structures 103a that constitute the first area A1 on a SiN film using, for example, electron beam lithography and dry etching, the periphery of each unit structure 103a may be embedded with polyimide and planarized by a damascene process.

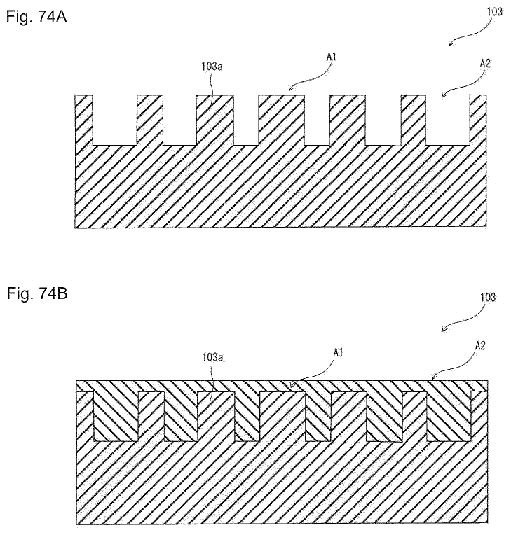

In addition, a longitudinal cross-sectional shape of each unit structure 103a may be a rectangular shape as in a longitudinal cross-section configuration example 1 of the metasurface 103 shown in FIG. 74A. In the example shown in FIG. 74A, upper ends of the respective unit structures 103a are on a same plane and lower ends are on a same plane. In this case, a bonding surface (joining surface) can be flattened to some extent. Here, the first area A1 is a dielectric body or a semiconductor and the second area A2 is a gas or a vacuum.

In addition, a longitudinal cross-sectional shape of each unit structure 103a may be a rectangular shape as in a longitudinal cross-section configuration example 2 of the metasurface 103 shown in FIG. 74B. In the example shown in FIG. 74B, a surface of the second area A2 in which a periphery of each unit structure 103a is to be embedded is planarized. In this case, a bonding surface (joining surface) can be sufficiently flattened. Here, the first area A1 is a dielectric body or a semiconductor and the second area A2 is a dielectric body or a semiconductor.

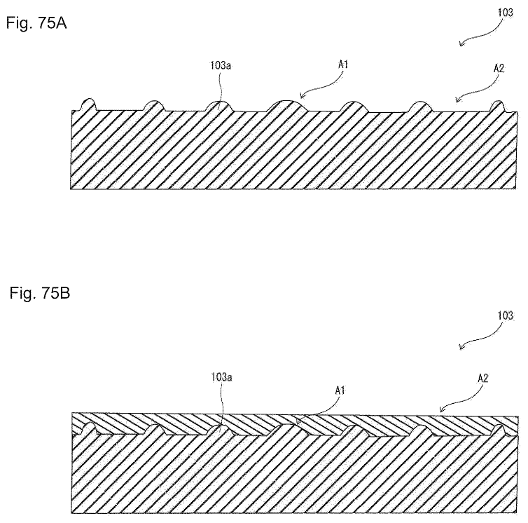

In addition, a longitudinal cross-sectional shape of each unit structure 103a may be a semi-circular shape or a semi-elliptical shape as in a longitudinal cross-section configuration example 3 of the metasurface 103 shown in FIG. 75A. In the example shown in FIG. 75A, lower ends of the respective unit structures 103a are on a same plane and upper ends are on a same plane. In this case, a bonding surface (joining surface) can be flattened to some extent. Here, the first area A1 is a dielectric body or a semiconductor and the second area A2 is a gas or a vacuum.

In addition, a longitudinal cross-sectional shape of each unit structure 103a may be a semi-circular shape or a semi-elliptical shape as in a longitudinal cross-section configuration example 4 of the metasurface 103 shown in FIG. 75B. In the example shown in FIG. 75B, a surface of the second area A2 in which a periphery of each unit structure 103a is to be embedded is planarized. In this case, a bonding surface (joining surface) can be sufficiently flattened. Here, the first area A1 is a dielectric body or a semiconductor and the second area A2 is a dielectric body or a semiconductor.

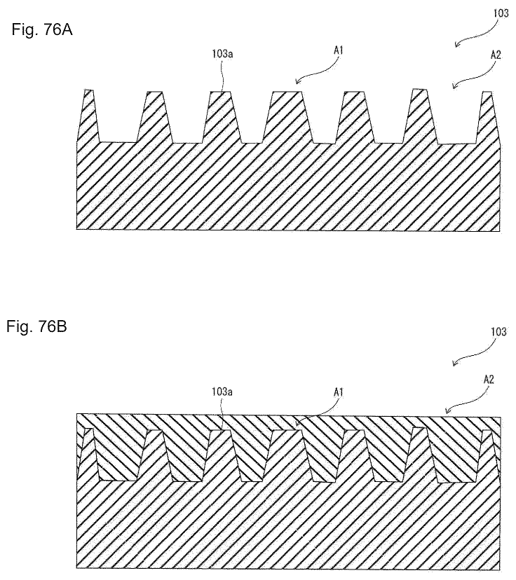

In addition, a longitudinal cross-sectional shape of each unit structure 103a may be a trapezoidal shape as in a longitudinal cross-section configuration example 5 of the metasurface 103 shown in FIG. 76A. In the example shown in FIG. 76A, upper ends of the respective unit structures 103a are on a same plane and lower ends are on a same plane. In this case, a bonding surface (joining surface) can be flattened to some extent. Here, the first area A1 is a dielectric body or a semiconductor and the second area A2 is a gas or a vacuum.

In addition, a longitudinal cross-sectional shape of each unit structure 103a may be a trapezoidal shape as in a longitudinal cross-section configuration example 6 of the metasurface 103 shown in FIG. 76B. In the example shown in FIG. 76B, a surface of the second area A2 in which a periphery of each unit structure 103a is to be embedded is planarized. In this case, a bonding surface (joining surface) can be sufficiently flattened. Here, the first area A1 is a dielectric body or a semiconductor and the second area A2 is a dielectric body or a semiconductor.

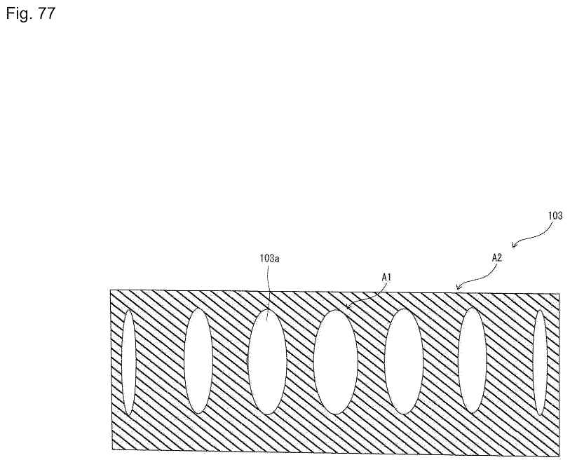

In addition, a longitudinal cross-sectional shape of each unit structure 103a may be an elliptical shape (which can be generated by regrowth of the second area A2) as in a longitudinal cross-section configuration example 7 of the metasurface 103 shown in FIG. 77. In the example shown in FIG. 77, upper ends of the respective unit structures 103a are on a same plane and lower ends are on a same plane. In this case, since the surface of the second area A2 after regrowth is planarized, a bonding surface (joining surface) can be sufficiently flattened. Here, the first area A1 is a gas or a vacuum and the second area A2 is a dielectric body or a semiconductor.

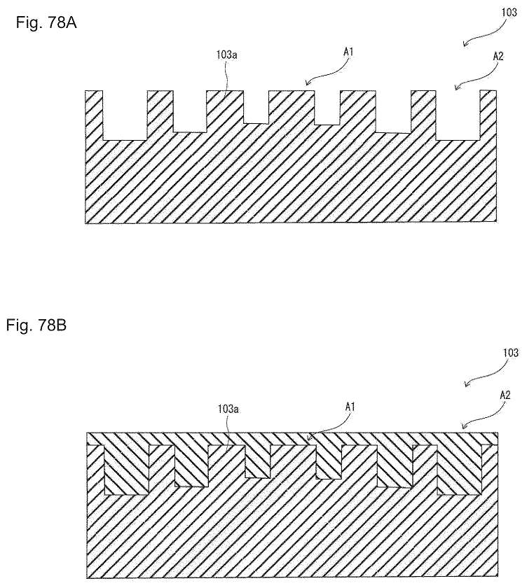

In addition, a longitudinal cross-sectional shape of each unit structure 103a may be a rectangular shape as in a longitudinal cross-section configuration example 8 of the metasurface 103 shown in FIG. 78A. In the example shown in FIG. 78A, upper ends of the respective unit structures 103a are on a same plane but heights differ from one another. In this case, a bonding surface (joining surface) can be flattened to some extent. Here, the first area A1 is a dielectric body or a semiconductor and the second area A2 is a gas or a vacuum.

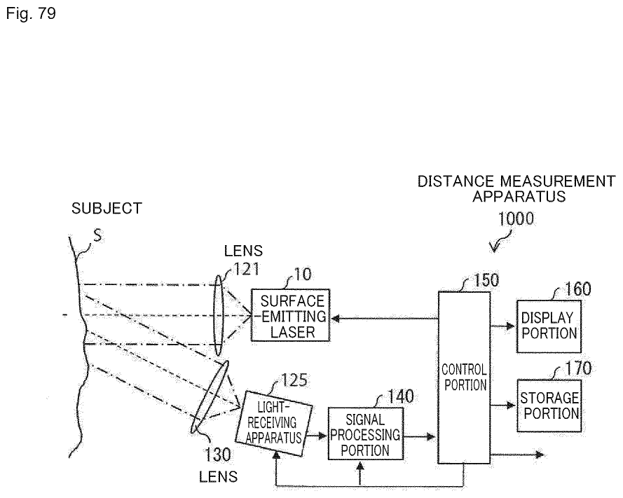

In addition, a longitudinal cross-sectional shape of each unit structure 103a may be a rectangular shape as in a longitudinal cross-section configuration example 9 of the metasurface 103 shown in FIG. 78B. In the example shown in FIG. 79B, a surface of the second area A2 in which a periphery of each unit structure 103a is to be embedded is planarized. In this case, a bonding surface (joining surface) can be sufficiently flattened. Here, the first area A1 is a dielectric body or a semiconductor and the second area A2 is a dielectric body or a semiconductor.

For example, current constriction in surface-emitting lasers is not limited to that caused by an ion implantation area. For example, current constriction may be performed by QWI which traps carriers by creating a band gap energy difference between inside and outside of an aperture through Ga vacancy diffusion or the like.

For example, the substrate 101 may be an Si substrate, a Ge substrate, a GaN substrate, an InP substrate, or the like. Any material with an oscillation wavelength in the 200 to 2000 nm wavelength band can be used in the surface-emitting lasers according to the present technique.

The first reflecting structure 102 and/or the second reflecting structure 108 preferably includes at least one of a semiconductor multilayer reflector, a dielectric multilayer reflector, a metal reflector, and high-contrast gratings.

The anode electrode and/or the cathode electrode may have a plating metal in addition to or in place of one of the contact metal and the pad metal.

The anode electrode and/or the cathode electrode may have a transparent conductive film.

The surface-emitting lasers according to each of the embodiments and each of the modifications described above may have a mesa structure. In this case, the metasurface 103 may be arranged at a position deviated from a current pathway or on the current pathway.

In the surface-emitting lasers according to each of the embodiments and each of the modifications described above, the conductive types (n-type and p-type) of the two conductive structures that sandwich the active layer 106 may be swapped.

Parts of the configurations of the surface-emitting lasers according to each of the embodiments and each of the modifications described above may be combined to the extent that they do not contradict each other.

In each of the embodiments and each of the modifications described above, the material, the conductivity type, the thickness, the width, the numerical value, the shape, the size, and the like of each layer constituting the surface-emitting laser can be changed as needed within the range of functioning as a surface-emitting laser.

### 6. EXAMPLE OF APPLICATION TO ELECTRONIC DEVICE

The technique according to the present disclosure (the present technique) can be applied to various products (electronic devices). For example, the technique according to the present disclosure may be realized as an apparatus to be mounted to any of various types of mobile bodies including an automobile, an electric vehicle, a hybrid electric vehicle, a motorcycle, a bicycle, personal mobility, an airplane, a drone, an ocean vessel, and a robot or a low power consumption device (for example, a smartphone, a smart watch, a tablet, or a mouse).

The surface-emitting lasers according to the present technique can also be applied, for example, as a light source for a device that forms or displays images by a laser beam (for example, a laser printer, a laser copier, a projector, a head-mounted display, or a head-up display).

### 7. EXAMPLE OF APPLICATION OF SURFACE-EMITTING LASER TO DISTANCE MEASUREMENT APPARATUS

Hereinafter, an application example of the surface-emitting lasers according to each embodiment and each modification described above will be described.

FIG. 79 represents an example of a schematic configuration of a distance measurement apparatus 1000 including the surface-emitting laser 10 as an example of an electronic device according to the present technique. The distance measurement apparatus 1000 measures a distance to a subject S using the TOF (Time Of Flight) method. The distance measurement apparatus 1000 includes the surface-emitting laser 10 as a light source. For example, the distance measurement apparatus 1000 includes the surface-emitting laser 10, a light-receiving apparatus 125, lenses 121 and 130, a signal processing portion 140, a control portion 150, a display portion 160, and a storage portion 170.

The light-receiving apparatus 125 detects light reflected by the subject S. The lens 121 is a collimating lens for collimating light emitted from the surface-emitting laser 10. The lens 130 is a condenser lens that collects the light reflected by the subject S and directs the light to the light-receiving apparatus 125.

The signal processing portion 140 is a circuit for generating a signal corresponding to a difference between a signal input from the light-receiving apparatus 125 and a reference signal input from the control portion 150. The control portion 150 is configured to include, for example, a Time to Digital Converter (TDC). The reference signal may be a signal input from the control portion 150 or an output signal of a detecting portion that directly detects an output of the surface-emitting laser 10. For example, the control portion 150 is a processor that controls the surface-emitting laser 10, the light-receiving apparatus 125, the signal processing portion 140, the display portion 160, and the storage portion 170. The control portion 150 is a circuit that measures the distance to the subject S based on a signal generated by the signal processing portion 140. The control portion 150 generates a video signal for displaying information regarding the distance to the subject S and outputs the video signal to the display portion 160. The display portion 160 displays the information regarding the distance to the subject S based on the video signal input from the control portion 150. The control portion 150 stores the information regarding the distance to the subject S in the storage portion 170.

In the present application example, any of the surface-emitting lasers 10-1, 10-2, 10-3, 10-4, 10-5, 10-6, 20-1, 20-2, 20-3, 20-4, 20-5, 20-6, 30, 40, and 40-1 described above can be applied to the distance measurement apparatus 1000 in place of the surface-emitting laser 10.

### 8. EXAMPLE OF DISTANCE MEASUREMENT APPARATUS MOUNTED TO MOBILE BODY

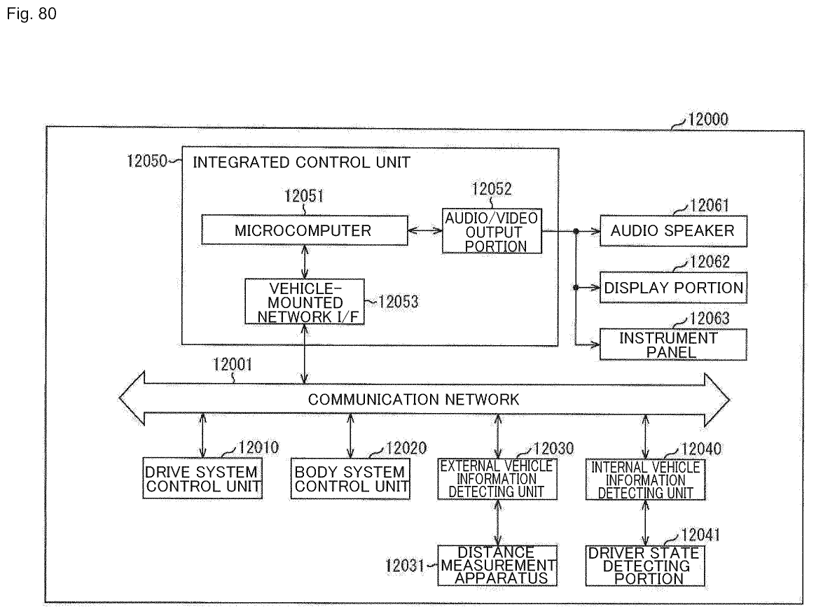

FIG. 80 is a block diagram showing a schematic configuration example of a vehicle control system that represents an example of a mobile body control system to which the technique according to the present disclosure may be applied.

A vehicle control system 12000 includes a plurality of electronic control units that are connected via a communication network 12001. In the example shown in FIG. 80, the vehicle control system 12000 includes a drive system control unit 12010, a body system control unit 12020, an external vehicle information detecting unit 12030, an internal vehicle information detecting unit 12040, and an integrated control unit 12050. In addition, as functional components of the integrated control unit 12050, a microcomputer 12051, an audio/video output portion 12052, and a vehicle-mounted network I/F (interface) 12053 are illustrated.

The drive system control unit 12010 controls operations of apparatuses related to a drive system of a vehicle in accordance with various programs. For example, the drive system control unit 12010 functions as a control apparatus of a drive force generation apparatus for generating a drive force of the vehicle such as an internal engine or a drive motor, a control apparatus of a drive force transmission mechanism for transmitting the drive force to wheels, a control apparatus of a steering mechanism for adjusting a steering angle of the vehicle, and a control apparatus of a braking apparatus that generates a brake force of the vehicle.

The body system control unit 12020 controls operations of various apparatuses mounted to the vehicle body in accordance with various programs. For example, the body system control unit 12020 functions as a control apparatus of a key-less entry system, a smart key system, a power window apparatus, or various lamps such as head lamps, tail lamps, brake lamps, turn indicators, and fog lamps. In this case, radio waves or signals of various switches which are transmitted from a portable device that substitutes as a key may be input to the body system control unit 12020. The body system control unit 12020 accepts input of the radio waves or signals and controls a door lock apparatus, the power window apparatus, the lamps, and the like of the vehicle.

The external vehicle information detecting unit 12030 detects information on an exterior of the vehicle that is mounted with the vehicle control system 12000. For example, a distance measurement apparatus 12031 is connected to the external vehicle information detecting unit 12030. The distance measurement apparatus 12031 includes the distance measurement apparatus 1000 described above. The external vehicle information detecting unit 12030 causes the distance measurement apparatus 12031 to measure a distance to an object (subject S) outside of the vehicle and acquires distance data obtained by the measurement. Based on the acquired distance data, the external vehicle information detecting unit 12030 may perform object detection processing with respect to people, vehicles, obstacles, signs, and the like.

The internal vehicle information detecting unit 12040 detects information on an interior of the vehicle. For example, a driver state detecting portion 12041 that detects a state of a driver is connected to the internal vehicle information detecting unit 12040. For example, the driver state detecting portion 12041 includes a camera for capturing an image of the driver and, based on detection information that is input from the driver state detecting portion 12041, the internal vehicle information detecting unit 12040 may calculate a degree of fatigue or a degree of concentration of the driver or may determine whether or not the driver has fallen asleep.

Based on information on the exterior or the interior of the vehicle acquired by the external vehicle information detecting unit 12030 or the internal vehicle information detecting unit 12040, the microcomputer 12051 can calculate a control target value of the drive force generation apparatus, the steering mechanism, or the brake apparatus and output a control command to the drive system control unit 12010. For example, the microcomputer 12051 can perform cooperative control for the purpose of realizing functions of an ADAS (Advanced Driver Assistance System) including collision avoidance or crash mitigation of the vehicle, headway control based on inter-vehicular distance, cruise control, collision warning of the vehicle, and lane departure warning of the vehicle.

In addition, by controlling the drive force generation apparatus, the steering mechanism, the brake apparatus, or the like based on information on a periphery of the vehicle acquired by the external vehicle information detecting unit 12030 or the internal vehicle information detecting unit 12040, the microcomputer 12051 can perform cooperative control for the purpose of automated driving or the like that enables the vehicle to travel autonomously without having to rely on operations by the driver.

Furthermore, based on information on the exterior of the vehicle acquired by the external vehicle information detecting unit 12030, the microcomputer 12051 can output a control command to the body system control unit 12020. For example, the microcomputer 12051 can perform cooperative control for the purpose of controlling the head lamps in accordance with a position of a vehicle ahead or an oncoming vehicle as detected by the external vehicle information detecting unit 12030 and realizing antidazzle by switching a high beam to a low beam or the like.

The audio/video output portion 12052 transmits an output signal of at least one of sound and an image to an output apparatus that is capable of audibly or visually notifying a passenger of the vehicle or the outside of the vehicle with information. In an example shown in FIG. 80, an audio speaker 12061, a display portion 12062, and an instrument panel 12063 are exemplified as output apparatuses. For example, the display portion 12062 may include at least one of an on-board display and a head-up display.

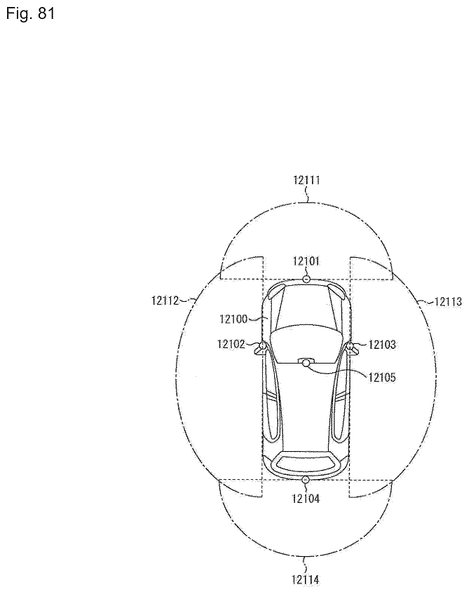

FIG. 81 is a diagram showing an example of an installation position of the distance measurement apparatus 12031.

In FIG. 81, as the distance measurement apparatus 12031, a vehicle 12100 has distance measurement apparatuses 12101, 12102, 12103, 12104, and 12105.

For example, the distance measurement apparatuses 12101, 12102, 12103, 12104, and 12105 are provided at positions such as a front nose, side mirrors, a rear bumper, a rear door, and an upper part of a front glass inside a cabin of the vehicle 12100. The distance measurement apparatus 12101 that is provided on the front nose and the distance measurement apparatus 12105 that is provided in the upper part of the front glass inside the cabin mainly acquire data of the front of the vehicle 12100. The distance measurement apparatuses 12102 and 12103 that are provided on the side mirrors mainly acquire data of the sides of the vehicle 12100. The distance measurement apparatus 12104 that is provided on the rear bumper or the rear door mainly acquires data of the rear of the vehicle 12100. The front data that is acquired by the distance measurement apparatuses 12101 and 12105 is mainly used to detect vehicles ahead, pedestrians, obstacles, traffic lights, traffic signs, and the like.

FIG. 81 shows an example of detection ranges of the distance measurement apparatuses 12101 to 12104. A detection range 12111 indicates a detection range of the distance measurement apparatus 12101 provided on the front nose, detection ranges 12112 and 12113 indicate detection ranges of the distance measurement apparatuses 12102 and 12103 provided on the side mirrors, respectively, and a detection range 12114 indicates a detection range of the distance measurement apparatus 12104 provided on the rear bumper or a back door.

For example, by obtaining a distance to each solid object in the detection ranges 12111 to 12114 and a temporal variation of the distance (a relative speed with respect to the vehicle 12100) based on the distance data obtained from the distance measurement apparatuses 12101 to 12104, particularly, the microcomputer 12051 can extract, as a vehicle ahead, a solid object which is closest to the vehicle 12100 on a path of the vehicle 12100 and which is traveling at a predetermined speed (for example, 0 km/h or higher) in approximately the same direction as the vehicle 12100. In addition, the microcomputer 12051 can set an inter-vehicular distance to be secured in advance behind a vehicle ahead and perform automatic brake control (including cruise stop control), automatic acceleration control (including cruise start control), and the like. As described above, cooperative control for the purpose of automated driving or the like that enables autonomous travel without having to rely on operations by the driver can be performed.

For example, based on the distance data obtained from the distance measurement apparatuses 12101 to 12104, the microcomputer 12051 can extract solid object data related to solid objects by classifying the solid objects into motorcycles, ordinary vehicles, large vehicles, pedestrians, utility poles, and other solid objects and use the solid object data for automatic obstacle avoidance. For example, the microcomputer 12051 distinguishes obstacles around the vehicle 12100 between obstacles that are visible from the driver of the vehicle 12100 and obstacles that are hardly visible. In addition, the microcomputer 12051 can perform driving support for collision avoidance by determining a collision risk that indicates a degree of danger of a collision with each obstacle, and in a situation where the collision risk is equal to or higher than a set value and where there is a possibility of a collision, issuing a warning to the driver via the audio speaker 12061 or the display portion 12062 or performing forced braking or evasive steering via the drive system control unit 12010.

This concludes the description of an example of a mobile body control system to which the technique according to the present disclosure may be applied. The technique according to the present disclosure may be applied to the distance measurement apparatus 12031 among the configuration described above.

In addition, the present technique can also be configured as follows.

(1) A surface-emitting laser, including a resonator that includes:
first and second reflecting structures; and
an active layer arranged between the first and second reflecting structures, wherein the resonator includes, between a surface of the first reflecting structure on an opposite side to a side of the active layer and the active layer and/or between a surface of the second reflecting structure on an opposite side to a side of the active layer and the active layer, a metasurface for generating in an in-plane direction an effective refractive index distribution that traps light.

(2) The surface-emitting laser according to (1), wherein a direction of resonance of the resonator is perpendicular to the in-plane direction.

(3) The surface-emitting laser according to any one of (1) and (2), wherein the metasurface is set not to form a stopband at an oscillation wavelength of the surface-emitting laser with respect to light propagating in the in-plane direction.

(4) The surface-emitting laser according to any one of (1) to (3), wherein the metasurface is arranged between the first reflecting structure and the active layer and/or between the second reflecting structure and the active layer.

(5) The surface-emitting laser according to any one of (1) to (4), wherein the metasurface is arranged inside at least one of the first and second reflecting structures.

(6) The surface-emitting laser according to any one of (1) to (5), wherein the metasurface has an area in which a refractive index gradually decreases from a reference point to an outer edge side in the in-plane direction.

(7) The surface-emitting laser according to any one of (1) to (6), wherein the metasurface has an area in which a refractive index decreases in a plurality of stages from a reference point to an outer edge side in the in-plane direction.

(8) The surface-emitting laser according to any one of (1) to (7), wherein
the metasurface includes:
a first area including a plurality of unit structures aligned in the in-plane direction; and
a second area surrounding each of the plurality of unit structures and having a refractive index different from that of the first area.

(9) The surface-emitting laser according to (8), wherein
the plurality of unit structures are arranged at a predetermined pitch in the in-plane direction, and
a duty ratio, which is a ratio of the unit structures to the pitch, varies in the in-plane direction.

(10) The surface-emitting laser according to (9), wherein
the first area has a higher refractive index than the second area, and
the duty ratio gradually decreases from a reference point to an outer edge side in the in-plane direction.

(11) The surface-emitting laser according to (9), wherein
the first area has a lower refractive index than the second area, and
the duty ratio gradually increases from a reference point to an outer edge side in the in-plane direction.

(12) The surface-emitting laser according to (9) or (10), wherein
the first area has a higher refractive index than the second area, and
the duty ratio decreases in a plurality of stages from a reference point to an outer edge side in the in-plane direction.

(13) The surface-emitting laser according to (9) or (11), wherein
the first area has a lower refractive index than the second area, and
the duty ratio increases in a plurality of stages from a reference point to an outer edge side in the in-plane direction.

(14) The surface-emitting laser according to any one of (8) to (13), wherein each of the plurality of unit structures is smaller than an oscillation wavelength of the surface-emitting laser.

(15) The surface-emitting laser according to any one of (8) to (14), wherein
the plurality of unit structures are arranged at a predetermined pitch in the in-plane direction, and
the pitch is shorter than an emission wavelength of the active layer.

(16) The surface-emitting laser according to any one of (8) to (15), wherein each of the plurality of unit structures has shape anisotropy in the in-plane direction.

(17) The surface-emitting laser according to (16), wherein each of the plurality of unit structures has the same shape anisotropy.

(18) The surface-emitting laser according to any one of (8) to (17), wherein a transverse cross-sectional shape of each of the plurality of unit structures is any of a polygonal shape, a circular shape, and an elliptical shape.

(19) The surface-emitting laser according to any one of (8) to (18), wherein a transverse cross-sectional shape of each of the plurality of unit structures is a shape with two-fold symmetry.

(20) The surface-emitting laser according to any one of (8) to (18), wherein a transverse cross-sectional shape of each of the plurality of unit structures is a shape with N-fold symmetry (N≥3).

(21) The surface-emitting laser according to any one of (8) to (20), wherein the plurality of unit structures are periodically arranged.

(22) The surface-emitting laser according to any one of (8) to (21), wherein the plurality of unit structures are arranged in any of a square lattice pattern, a rectangular lattice pattern, a six law lattice pattern, and a rhombic lattice pattern.

(23) The surface-emitting laser according to any one of (8) to (22), wherein a longitudinal cross-sectional shape of each of the plurality of unit structures is any of a rectangular shape, at least a part of a circular shape, at least a part of an elliptical shape, and a trapezoidal shape.

(24) The surface-emitting laser according to any one of (8) to (23), wherein the plurality of unit structures are arranged at a position deviated from a current pathway during driving in the resonator.

(25) The surface-emitting laser according to any one of (1) to (24), wherein both the first and second reflecting structures has a reflectance of 90% or higher with respect to an oscillation wavelength of the surface-emitting laser.

(26) The surface-emitting laser according to any one of (8) to (25), wherein one of the first and second areas is a gas or a vacuum and the other is a dielectric body or a semiconductor.

(27) The surface-emitting laser according to any one of (8) to (25), wherein one of the first and second areas is a dielectric body and the other is a semiconductor.

(28) The surface-emitting laser according to any one of (8) to (25), wherein the first and second areas are dielectric bodies.

(29) The surface-emitting laser according to any one of (8) to (28), wherein an upper end and a lower end of a longitudinal cross-section of each of the plurality of unit structures exist on a same plane.

(30) The surface-emitting laser according to any one of (8) to (29), wherein an outer edge of a longitudinal cross-section of each of the plurality of unit structures includes a curved line.

(31) The surface-emitting laser according to any one of (1) to (30), wherein the first reflecting structure and/or the second reflecting structure include at least one of a semiconductor multilayer reflector, a dielectric multilayer reflector, a metal reflector, and high-contrast gratings.

(32) The surface-emitting laser according to any one of (1) to (31), wherein the resonator further includes a current constriction area arranged between a surface of the first reflecting structure on an opposite side to a side of the active layer and a surface of the second reflecting structure on an opposite side to a side of the active layer.

(33) An electronic device including the surface-emitting laser according to any one of (1) to (32).

### REFERENCE SIGNS LIST

10, 10-1, 10-2, 10-3, 10-4, 10-5, 10-6, 20-1, 20-2, 20-3, 20-4, 20-5, 20-6, 30, 40, 40-1 Surface-emitting laser
102 First reflecting structure
103 Metasurface
103a Unit structure
106 Active layer
108 Second reflecting structure
HCG High-contrast grating
P Pitch
D/P Duty ratio
RIDA Refractive index distribution area (area)
A1 First area
A2 Second area
RP Reference point
R Resonator
IIA Ion implantation area (current constriction area)

1. A surface-emitting laser, comprising a resonator that includes:
first and second reflecting structures; and
an active layer arranged between the first and second reflecting structures, wherein the resonator includes, between a surface of the first reflecting structure on an opposite side to a side of the active layer and the active layer and/or between a surface of the second reflecting structure on an opposite side to a side of the active layer and the active layer, a metasurface for generating in an in-plane direction an effective refractive index distribution that traps light.

2. The surface-emitting laser according to claim 1, wherein a direction of resonance of the resonator is perpendicular to the in-plane direction.

3. The surface-emitting laser according to claim 1, wherein the metasurface is set not to form a stopband at an oscillation wavelength of the surface-emitting laser with respect to light propagating in the in-plane direction.

4. The surface-emitting laser according to claim 1, wherein the metasurface is arranged between the first reflecting structure and the active layer and/or between the second reflecting structure and the active layer.

5. The surface-emitting laser according to claim 1, wherein the metasurface is arranged inside at least one of the first and second reflecting structures.

6. The surface-emitting laser according to claim 1, wherein the metasurface has an area in which a refractive index gradually decreases from a reference point to an outer edge side in the in-plane direction.

7. The surface-emitting laser according to claim 1, wherein the metasurface has an area in which a refractive index decreases in a plurality of stages from a reference point to an outer edge side in the in-plane direction.

8. The surface-emitting laser according to claim 1, wherein
the metasurface includes:
a first area including a plurality of unit structures aligned in the in-plane direction; and
a second area surrounding each of the plurality of unit structures and having a material refractive index different from that of the first area.

9. The surface-emitting laser according to claim 8, wherein
the plurality of unit structures are arranged at a predetermined pitch in the in-plane direction, and
a duty ratio, which is a ratio of the unit structures to the pitch, varies in the in-plane direction.

10. The surface-emitting laser according to claim 9, wherein
the first area has a higher material refractive index than the second area, and
the duty ratio gradually decreases from a reference point to an outer edge side in the in-plane direction.

11. The surface-emitting laser according to claim 9, wherein
the first area has a lower material refractive index than the second area, and
the duty ratio gradually increases from a reference point to an outer edge side in the in-plane direction.

12. The surface-emitting laser according to claim 9, wherein
the first area has a higher material refractive index than the second area, and
the duty ratio decreases in a plurality of stages from a reference point to an outer edge side in the in-plane direction.

13. The surface-emitting laser according to claim 9, wherein
the first area has a lower material refractive index than the second area, and
the duty ratio increases in a plurality of stages from a reference point to an outer edge side in the in-plane direction.

14. The surface-emitting laser according to claim 8, wherein
each of the plurality of unit structures is smaller than an oscillation wavelength of the surface-emitting laser.

15. The surface-emitting laser according to claim 8, wherein
the plurality of unit structures are arranged at a predetermined pitch in the in-plane direction, and
the pitch is shorter than an emission wavelength of the active layer.

16. The surface-emitting laser according to claim 8, wherein each of the plurality of unit structures has shape anisotropy in the in-plane direction.

17. The surface-emitting laser according to claim 16, wherein each of the plurality of unit structures has the same shape anisotropy.

18. The surface-emitting laser according to claim 8, wherein a transverse cross-sectional shape of each of the plurality of unit structures is any of a polygonal shape, a circular shape, and an elliptical shape.

19. The surface-emitting laser according to claim 8, wherein a transverse cross-sectional shape of each of the plurality of unit structures is a shape with two-fold symmetry.

20. The surface-emitting laser according to claim 8, wherein a transverse cross-sectional shape of each of the plurality of unit structures is a shape with N-fold symmetry (N≥3).

21. The surface-emitting laser according to claim 8, wherein the plurality of unit structures are periodically arranged.

22. The surface-emitting laser according to claim 21, wherein the plurality of unit structures are arranged in any of a square lattice pattern, a rectangular lattice pattern, a six law lattice pattern, and a rhombic lattice pattern.

23. The surface-emitting laser according to claim 8, wherein a longitudinal cross-sectional shape of each of the plurality of unit structures is any of a rectangular shape, at least a part of a circular shape, at least a part of an elliptical shape, and a trapezoidal shape.

24. The surface-emitting laser according to claim 8, wherein the plurality of unit structures are arranged at a position deviated from a current pathway during driving in the resonator.

25. The surface-emitting laser according to claim 1, wherein both the first and second reflecting structures has a reflectance of 90% or higher with respect to an oscillation wavelength of the surface-emitting laser.

26. The surface-emitting laser according to claim 8, wherein one of the first and second areas is a gas or a vacuum and the other is a dielectric body or a semiconductor.

27. The surface-emitting laser according to claim 8, wherein one of the first and second areas is a dielectric body and the other is a semiconductor.

28. The surface-emitting laser according to claim 8, wherein the first and second areas are dielectric bodies.

29. The surface-emitting laser according to claim 8, wherein an upper end and a lower end of a longitudinal cross-section of each of the plurality of unit structures exist on a same plane.

30. The surface-emitting laser according to claim 8, wherein an outer edge of a longitudinal cross-section of each of the plurality of unit structures includes a curved line.

31. The surface-emitting laser according to claim 1, wherein the first reflecting structure and/or the second reflecting structure include at least one of a semiconductor multilayer reflector, a dielectric multilayer reflector, a metal reflector, and high-contrast gratings.

32. The surface-emitting laser according to claim 1, wherein the resonator further includes a current constriction area arranged between a surface of the first reflecting structure on an opposite side to a side of the active layer and a surface of the second reflecting structure on an opposite side to a side of the active layer.
